(19) United States
(12) Patent Application Publication
(10) Pub. No.: US 2006/0081962 A1
(43) Pub. Date: Apr. 20, 2006

(54) Variable resistance device made of a material which has an electric resistance value changing in accordance with an applied electric field and maintains the electric resistance value after being changed in a nonvolatile manner, and a semiconductor apparatus including the same

(75) Inventors: Zhiqiang Wei, Ibaraki-shi (JP); Yoshihisa Kato, Otsu-shi (JP)

Correspondence Address: MCDERMOTT WILL & EMERY LLP, 600 13TH STREET, N.W., WASHINGTON, DC, 20005-3096, US

(73) Assignee: MATSUSHITA ELECTRIC INDUSTIAL CO., LTD.

(21) Appl. No.: 11/231,807

(22) Filed: Sep. 22, 2005

(30) Foreign Application Priority Data
Oct. 19, 2004 (JP) 2004-304438

(51) Int. Cl. H01L 29/00; H01L 29/76

(52) U.S. Cl. 257/537; 257/536; 257/379

(57) ABSTRACT

The variable resistance device of the present invention comprises a variable resistance layer. The variable resistance layer is made of a material which has an electric resistance changing in accordance with an applied electric field and maintains the electric resistance after being changed in a nonvolatile manner. Provided for the variable resistance layer are four electrodes independent of each other. Of them, two electrodes constitute a control electrode pair, while the remaining two electrodes constituting a read electrode pair. The controle electrode pair is formed for applying an electric field to the variable resistance layer. On the other hand, the read electrode pair is formed as a data path making use of changes in the electric resistance.

### BACKGROUND OF THE INVENTION

[1] Field of the Invention

The present invention relates to: a variable resistance device made of a material which has an electric resistance changing in accordance with an applied electric field and maintains the electric resistance after being changed in a nonvolatile manner; and a semiconductor apparatus including the variable resistance device, and in particular relates to the electrode structure of the variable resistance device.

[2] Related Art

Materials having a perovskite structure, especially colossal magnetoresistive (CMR) materials, have electric properties changing due to the influence of external factors such as a magnetic field. Research and development for applying such materials to electronic apparatuses are being carried out. One example of such CMR materials is Pr_{0.7}Ca_{0.3}MnO₃ (referred to hereinafter as “PCMO”), and the electric properties of this can be changed by applying a pulse once or more.

In conventional technologies for constructing a device made of a material having a perovskite structure, two electrodes are formed onto a thin film made of a CMR material or a bulk CMR material, and an electric pulse is applied between the electrode pair which performs detection of the electric properties. Here, the intensity of the electric field created by a single or multiple voltage pulses is sufficiently high to convert the physical state of the CMR material so that the electric properties are changed. One of the electric properties to be changed is the electric resistance of the CMR material. A reverse change can be achieved by applying a pulse or pulses having the opposite polarity of the single or multiple pulses used to induce the initial change. A technology for applying CMR materials having such characteristics to switching elements has been researched and developed (e.g. U.S. patent Publication No. 6,583,003; and International Electron Device Meeting Technical Digest, 2002, p. 193).

Conventional technologies discussed in these references are described with reference to FIG. 1.

As shown in FIG. 1, impurity-diffused portions 524 are formed within a Si substrate 521, extending inwardly from the surface thereof. Then, layered structures, each of which is composed of a gate oxide layer 525 and a gate electrode 526, and underside electrodes 52A are formed. Laid on top of the gate electrodes 526 are word lines 527, while a variable resistance layer 523 made of PCMO and an upside electrode 52B are successively laid on each underside electrode 52A. Of them, portions carrying out a function as a variable resistance device (referred to hereinafter as “variable resistance portions”) are where the variable resistance layers 523 are sandwiched between the underside electrodes 52A and upside electrodes 52B.

The variable resistance portions are, for example, brought into a set state (i.e. a high electric resistance state) when a positive pulse is applied between the underside electrodes 52A and upside electrodes 52B while being brought into a reset state (a low electric resistance state) when a negative pulse is applied between these electrodes 52A and 52B. Additionally, in the conventional device shown in FIG. 1, the underside and upside electrodes 52A and 52B applying a voltage pulse are used as data paths making use of changes in the electric resistances.

### SUMMARY OF THE INVENTION

However, since the electrodes 52A and 52B applying a voltage pulse to the variable resistance layers 523 are also used as the data paths, the above-mentioned conventional technology has a number of limitations in constructing an electronic circuit in which the variable resistance portions are incorporated, which results in reducing flexibility in the designing. For example, when such a conventional variable resistance device is used as switches, there are two types of signals—a control signal for controlling the switches and a data signal controlled by the switches. If the control signal and data signal share two electrodes 52A and 52B of the device, another variable resistance element is required in order to switch these two types of signals.

The present invention has been made in order to solve the above problem, and aims at offering a variable resistance device that (1) ensures reliable detection of changes in the electric properties created by applying an electric field, and (2) provides high flexibility in the design of an electronic circuit by reducing the limitations of the electronic circuit of when the variable resistance device is incorporated therein. Besides, the present invention also aims at providing a semiconductor apparatus having this variable resistance device.

In order to accomplish the above objectives, the variable resistance device according to the present invention comprises: a variable resistance layer made of a material which has an electric resistance changing in accordance with an applied electric field and maintains the electric resistance after being changed in a nonvolatile manner; a control electrode pair, which consists of a 1st and a 2nd electrode respectively connected to the variable resistance layer so as to be independent of each other, being used for applying voltage to the variable resistance layer; and a read electrode, which is a 3rd electrode connected to the variable resistance layer so as to be independent of the 1st and the 2nd electrodes, being used for detecting the electric resistance.

In the variable resistance device according to the present invention, the read electrode is formed by the 3rd electrode that differs from the 1st and 2nd electrodes composing the control electrode pair, and therefore the control and the data path in the variable resistance device are separated from each other. Accordingly, the variable resistance device of the present invention is effective in reducing the limitations of an electronic circuit of when the variable resistance device is incorporated therein, and therefore, offers an advantage of providing higher flexibility in the design of an electronic circuit.

Consequently, the variable resistance device of the present invention has advantages of (1) ensuring reliable detection of changes in the electric properties created by applying an electric field, and (2) providing high flexibility in the design of an electronic circuit by reducing the limitations of the electronic circuit of when the variable resistance device is incorporated therein.

The following two structures can for instance be adopted by the control electrode pair and the read electrode in the variable resistance device of the present invention.

First, in the variable resistance device according to the present invention, the 3rd electrode and one of the 1st and the 2nd electrodes constituting the control electrode pair may constitute a read electrode pair. When such a structure is adopted, either one of the 1st and 2nd electrodes serves as a shared electrode functioning as one of the control electrode pair as well as the read electrode, and the remaining one of the 1st and 2nd electrodes exclusively functions as the other one of the control electrode pair. Accordingly, the variable resistance device of the present invention offers high flexibility in the design of an electronic circuit, and the structure of the variable resistance device itself is simplified.

Second, in the variable resistance device according to the present invention, a 4th electrode which is independent of the respective 1st, 2nd and 3rd electrodes is provided, and a read electrode pair can be composed of the 3rd and the 4th electrodes. When such a structure is adopted, the control and the data path are completely separated from each other, which results in a further increase in flexibility in the designinig.

Additionally, it is desirable that the variable resistance device of the present invention adopts a structure in which the 1st and 2nd electrodes constituting the control electrode pair are arranged to sandwich an entire or part of the variable resistance layer therebetween in the thickness direction, and the electrodes constituting the read electrode pair are positioned so that at least part of a section, within the variable resistance layer, sandwiched between the control electrode pair is included in the target path for detecting the electric resistance. By adopting the above structure, an electric-variable resistance portion of the variable resistance device is formed to exist in the detection target path between the read electrode pair. As a result, the electric resistance of the data path can be changed without changing the electric resistance of the entire variable resistance layer, which allows to lower the power consumption.

Additionally, it is desirable, with the objective of lowering the power consumption, that the variable resistance device of the present invention adopts a structure in which a high dielectric constant layer, having a dielectric constant of at least 90% of a dielectric constant of the variable resistance layer in the insulating phase, is interposed between the variable resistance layer and at least one of the electrodes constituting the control electrode pair. That is, the above-mentioned conventional variable resistance device has a problem of high power consumption since the electric resistivity of the variable resistance layer, which is made of PCMO, in a low electric resistance state is small and the amount of electric current flowing through the data path during the reset state is large. On the other hand, by adopting the structure in which the high dielectric constant layer is interposed, the variable resistance device of the present invention is capable of reducing a through current flowing between the control electrode pair when voltage is applied to a layered structure composed of the high dielectric constant layer and the variable resistance layer, which allows to lower the power consumption.

Additionally, it is desirable, with the objective of preventing leakage current in the high dielectric constant layer between the read electrode pair, that the electric resistance of the high dielectric constant layer is set to have an electric resistivity equivalent to or greater than the electric resistivity of the variable resistance layer in the insulating phase, when the variable resistance device of the present invention adopts the structure in which the high dielectric constant layer is interposed.

It is desirable, with the objective of the stability of the high dielectric constant layer at a time when it is formed as a film, that the high dielectric constant layer includes a material expressed in a chemical composition formula of A_{X}B_{Y}. Here, A is at least one element selected from the group consisting of Al, Hf, Zr, Ti, Ba, Sr, Ta, La, Si, and Y; and B is at least one element selected from the group consisting of O, N, and F.

Reliable switching operation is made possible if the variable resistance device of the present invention adopts a layer having a following characteristic as the variable resistance layer: when a voltage pulse is applied to the control electrode pair once or a plurality of times, crystal condition of a portion, within the variable resistance layer, affected by the voltage pulse turns into one of the metallic phase and the insulating phase depending on the polarity of the voltage pulse. Here, the phase state of the variable resistance layer can be specifically controlled by adjusting at least one parameter selected from the group consisting of the number of voltage pulses applied to the control electrode pair, the pulse width, and the voltage value.

In the variable resistance device of the present invention, the variable resistance layer with the above characteristic may be constructed by including a colossal magnetoresistive material having a perovskite structure. To be more specific, the variable resistance layer may be constructed by including a material expressed in a chemical composition formula of A_{X}A′_{(1-X)}B_{Y}O_{Z}. Here, in the chemical composition formula, A is at least one element selected from the group consisting of La, Ce, Bi, Pr, Nd, Pm, Sm, Y, Sc, Yb, Lu, and Gd; A′ is at least one element selected from the group consisting of Mg, Ca, Sr, Ba, Pb, Zn, and Cd; B is at least one element selected from the group consisting of Mn, Ce, V, Fe, Co, Nb, Ta, Cr, Mo, W, Zr, Hf, and Ni; 0≦X≦1; 0≦Y≦2; and 1≦Z≦7.

A material having the above chemical composition formula, included as a constituent of the variable resistance layer, is for instance a material expressed as Pr_{0.7}Ca_{0.3}MnO₃.

The semiconductor apparatus of the present invention comprises: at least one variable resistance device. The variable resistance device includes: a variable resistance layer made of a material which has an electric resistance changing in accordance with an applied electric field and maintains the electric resistance after being changed in a nonvolatile manner; a control electrode pair, which consists of a 1st and a 2nd electrode respectively connected to the variable resistance layer so as to be independent of each other, being used for applying voltage to the variable resistance layer; and a read electrode, which is a 3rd electrode connected to the variable resistance layer so as to be independent of the 1st and the 2nd electrodes, being used for detecting the electric resistance. Here, the control electrode pair is formed for applying an electric field to the variable resistance layer while the read electrode is formed for detecting the electric resistance of the variable resistance layer.

The semiconductor apparatus of the present invention with the above structure includes a variable resistance device in which the control electrodes and the data path are separated from each other. Consequently, the semiconductor of the present invention is capable of (1) ensuring reliable detection of changes in the electric properties created by applying an electric field, and (2) providing high flexibility in the designing by reducing the limitations of the electronic circuit.

The present invention is effective, for example, for achieving semiconductor apparatuses respectively having: a nonvolatile memory unit; a nonvolatile flip-flop unit; a nonvolatile shift register unit; a nonvolatile look-up table unit; and a programmable logic circuit unit. If the variable resistance device of the present invention above is applied to these semiconductor apparatuses, it is possible to reduce the limitations of the electric circuit as described above and to thereby increase flexibility in the designing.

### BRIEF DESCRIPTION OF THE DRAWINGS

These and other objects, advantages and features of the invention will become apparent from the following description thereof taken in conjunction with the accompanying drawings which illustrate specific embodiments of the invention. In the drawings:

FIG. 1 is a schematic cross section of relevant parts showing a structure of a variable resistance device according to a prior art;

FIG. 2A is a schematic plain view of relevant parts of a variable resistance device 10 according to Embodiment 1;

FIG. 2B is a schematic cross section of relevant parts of the variable resistance device 10 along the line A-A;

FIG. 2C is an equivalent circuit diagram of the variable resistance device 10;

FIG. 3A is a schematic cross section of relevant parts of a variable resistance device 20 according to Modification 1;

FIG. 3B is an equivalent circuit diagram of the variable resistance device 20;

FIG. 4A is a schematic cross section of relevant parts of a variable resistance device 30 according to Modification 2;

FIG. 4B is an equivalent circuit diagram of the variable resistance device 30;

FIG. 5A is a schematic cross section of relevant parts of a variable resistance device 40 according to Embodiment 2;

FIG. 5B is an equivalent circuit diagram of the variable resistance device 40;

FIG. 6A is a schematic cross section of relevant parts of a variable resistance device 50 according to Modification 3;

FIG. 6B is an equivalent circuit diagram of the variable resistance device 50;

FIG. 7A is a schematic cross section of relevant parts of a variable resistance device 60 according to Modification 4;

FIG. 7B is an equivalent circuit diagram of the variable resistance device 60;

FIG. 8A is a schematic cross section of relevant parts of a variable resistance device 70 according to Modification 5;

FIG. 8B is an equivalent circuit diagram of the variable resistance device 70;

FIG. 9A is a schematic cross section of relevant parts of a variable resistance device 80 according to Modification 6;

FIG. 9B is an equivalent circuit diagram of the variable resistance device 80;

FIG. 10A is a schematic cross section of relevant parts of a variable resistance device 90 according to Modification 7;

FIG. 10B is an equivalent circuit diagram of the variable resistance device 90;

FIG. 11A is a schematic cross section of relevant parts of a variable resistance device 100 according to Modification 8;

FIG. 11B is an equivalent circuit diagram of the variable resistance device 100;

FIG. 12A is a schematic cross section of relevant parts of a variable resistance device 110 according to Embodiment 3;

FIG. 12B is an equivalent circuit diagram of the variable resistance device 110;

FIG. 13A is a schematic cross section of relevant parts of a variable resistance device 120 according to Modification 9;

FIG. 13B is an equivalent circuit diagram of the variable resistance device 80;

FIG. 14A is a schematic cross section of relevant parts of a variable resistance device 130 according to Modification 10;

FIG. 14B is an equivalent circuit diagram of the variable resistance device 130;

FIG. 15A is a schematic cross section of relevant parts of a variable resistance device 140 according to Modification 11;

FIG. 15B is an equivalent circuit diagram of the variable resistance device 140;

FIG. 16A is a schematic cross section of relevant parts of a variable resistance device 150 according to Modification 12;

FIG. 16B is an equivalent circuit diagram of the variable resistance device 150;

FIG. 17A is a schematic cross section of relevant parts of a variable resistance device 160 according to Modification 13;

FIG. 17B is an equivalent circuit diagram of the variable resistance device 160;

FIG. 18 is a schematic circuit diagram of relevant parts showing a memory array structure of a semiconductor apparatus 170 according to Embodiment 4;

FIG. 19 is a schematic circuit diagram of relevant parts showing a memory array structure of a semiconductor apparatus 180 according to Modification 14;

FIG. 20A is a block structure diagram of relevant parts showing a programmable logic device of a semiconductor apparatus 190 according to Embodiment 5;

FIG. 20B is a schematic structure diagram showing a switch point 193 of the programmable logic device of the semiconductor apparatus 190 according to Embodiment 5;

FIG. 20C is an equivalent circuit diagram of each of nonvolatile variable resistance devices S1 to S6 composing the switch point 193 according to Embodiment 5;

FIG. 21 is a block structure diagram showing an example of a logic circuit cell 191 in the programmable logic device of the semiconductor apparatus 190 according to Embodiment 5;

FIG. 22 is a block structure diagram showing a 2-input 1-output look-up table 194 which is a constituent part of the logic circuit cell 191 according to Embodiment 5;

FIG. 23 is a block structure diagram showing a nonvolatile flip-flop 195 which is another constituent part of the logic circuit cell 191 according to Embodiment 5;

FIG. 24A is a schematic circuit diagram showing a semiconductor apparatus 200 according to Embodiment 6;

FIG. 24B is a schematic circuit diagram showing a semiconductor apparatus 205 according to Embodiment 7; and

FIG. 25 is a graph showing electric field dependency of the rate of electric resistance change of variable resistance devices.

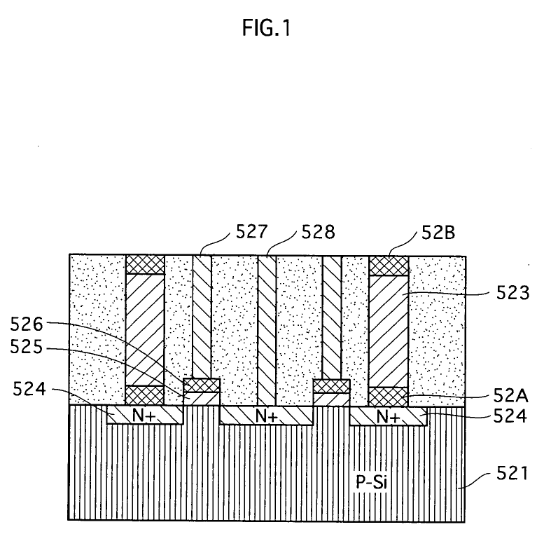

### DESCRIPTION OF PREFERRED EMBODIMENTS

The best modes for implementing the present invention are described next with the aid of drawings. Note that embodiments and modifications described below are merely examples for illustrating the structures and functions of the present invention, and therefore the present invention is not confined to these.

### 1. Embodiment 1

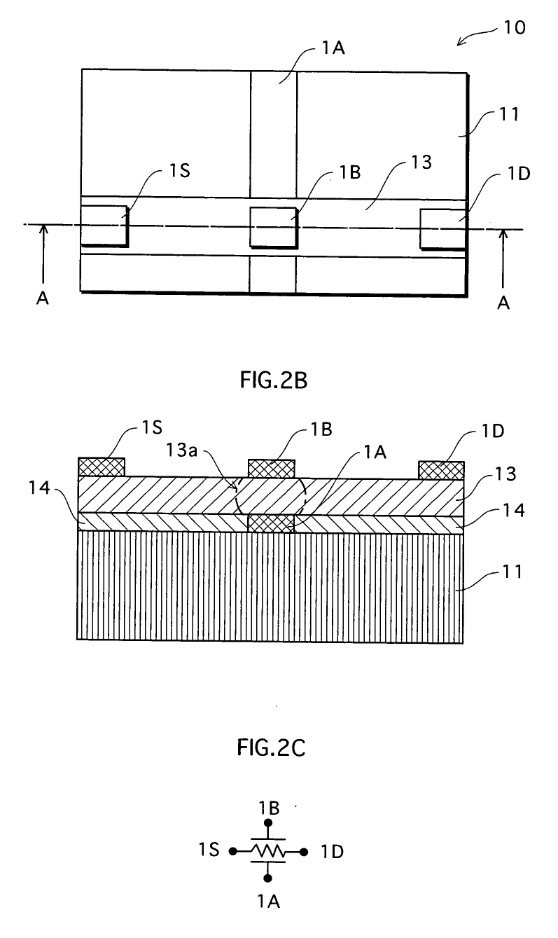

A variable resistance device 10 according to Embodiment 1 is described below in reference to FIGS. 2A to 2C. FIG. 2A is a plain view showing relevant parts of the variable resistance device 10; FIG. 2B is a schematic cross section of the variable resistance device 10 along the line A-A; and FIG. 2C is an equivalent circuit diagram of the variable resistance device 10.

1.1 Structure of Variable Resistance Device 10

The variable resistance device 10 has a layered structure in which a 1st electrode 1A and a planarizing layer (for example, a silicon oxide layer) 14 are formed on the main surface of a substrate (for example, a silicon substrate) 11, and a variable resistance layer 13 is formed on top of the 1st electrode 1A and planarizing layer 14, as shown in FIGS. 2A and 2B. On the surface of the variable resistance layer 13, a 2nd electrode 1B, a 3rd electrode 1S and a 4th electrode 1D are formed. As shown in FIG. 2A, the 3rd, 2nd and 4th electrodes 1S, 1B and 1D are arranged on the variable resistance layer 13 from the left to right in FIG. 2B, in the stated order. Among the three electrodes 1B, 1S and 1D on the variable resistance layer 13, the 2nd electrode 1B is formed so as to sandwich the variable resistance layer 13 between the 2nd and 1st electrodes 1B and 1A in the thickness direction.

The variable resistance layer 13 has the property that its crystal condition changes by the application of an electric field, and is made of a colossal magnetoresistive (CMR) material having a perovskite structure, such as Pr_{0.7}Ca_{0.3}MnO₃ (PCMO), for example.

Among the four electrodes 1A, 1B, 1S and 1D in the variable resistance device 10, the 1st and 2nd electrodes 1A and 1B, which are formed to sandwich the variable resistance layer 13 therebetween in the thickness direction, function as a pair of control electrodes for applying an electric field to the variable resistance layer 13. On the other hand, the 3rd and 4th electrodes 1S and 1D, which are provided at the edges of the variable resistance layer 13 so as to oppose each other across the 2nd electrode 1B in the direction along the surface of the variable resistance layer 13 (i.e. the horizontal direction in FIG. 2B), function as a pair of read electrodes for detecting the electric resistance of the variable resistance layer 13.

As has been described, the variable resistance device 10 forms a four-terminal nonvolatile variable resistance device.

1.2 Driving of Variable Resistance Device 10

When the variable resistance device 10 is driven, a voltage pulse (an electric field pulse) is applied between the 1st and 2nd electrodes 1A and 1B once or several times. With the application of the voltage pulse, the electric resistance of a portion 13a in the variable resistance layer 13, sandwiched between the 1st and 2nd electrodes 1A and 1B (hereinafter, referred to as a “variable resistance portion”) changes according to the applied electric field. Subsequently, in the variable resistance device 10, an electric current flowing between the 3rd and 4th electrodes 1S and 1D on the surface of the variable resistance layer 13 alters due to the electric resistance change, and the electric resistance of the variable resistance portion 13a, after the change, is maintained in a nonvolatile manner. FIG. 2C shows an equivalent circuit diagram of such a variable resistance device 10.

As shown in FIG. 2C, in the variable resistance device 10 according to the present embodiment, the four electrodes 1A, 1B, 1S and 1D are formed on the variable resistance layer 13 so that the 1st and 2nd electrodes 1A and 1B composing the control electrode pair are independent of the 3rd and 4th electrodes 1S and 1D composing the read electrode pair which serves as a data path making use of the change in electric resistance of the variable resistance layer 13.

1.3 Advantages of Variable Resistance Device 10

In the variable resistance device 10 according to the present embodiment, the control electrode pair comprising the 1st and 2nd electrodes 1A and 1B and the read electrode pair comprising the 3rd and 4th electrodes 1S and 1D are arranged to be independent of each other. By adopting such a structure, the circuit structure of an electronic circuit having the variable resistance device 10 according to the present embodiment can be simplified. Accordingly, this increases flexibility in the design of a semiconductor apparatus including the variable resistance device 10.

In addition, in the variable resistance device 10, the 3rd and 4th electrodes 1S and 1D composing the read electrode pair are arranged so that the variable resistance portion 13a in the variable resistance layer 13 is formed to exist in the current path between these electrodes 1S and 1D. According to the positioning of the electrodes 1S and 1D, the electric current between the 3rd and 4th electrodes 1S and 1D in the variable resistance device 10 can be effectively altered without changing the electric resistance of the entire variable resistance layer 13. As a result, it is possible to lower the overall power consumption of the variable resistance device 10.

In addition, as to the variable resistance device 10 according to the present embodiment, the variable resistance layer 13 is made of PCMO. Herewith, when a voltage pulse (an electric field pulse) is applied between the 1st and 2nd electrodes 1A and 1B in the variable resistance device 10, the crystal condition of the variable resistance layer 13 has a transition from the metallic phase (a second state exhibiting conducting behavior) to the insulating phase (a first state exhibiting insulating behavior), or from the insulating phase to the metallic phase, depending on the polarity of the electric field pulse. In the variable resistance device 10, due to the phase transition, the change in electric resistance of the variable resistance portion 13a in the variable resistance layer 13 becomes significantly high (the ratio of the electric resistivity in the insulating phase to the electric resistance in the metallic phase is 100 or more), which enables reliable switching operation.

For the formation of the variable resistance layer 13, the following materials may be used other than the PCMO material mentioned above. That is, a material expressed in a chemical composition formula of A_{X}A′_{(1-X)}B_{Y}O_{Z} can be used for the variable resistance layer 13, and it is desirable that A, A′, B, X, Y and Z be defined as follows:
A: at least one element selected from the group consisting of La, Ce, Bi, Pr, Nd, Pm, Sm, Y, Sc, Yb, Lu and Gd;
A′: at least one element selected from the group consisting of Mg, Ca, Sr, Ba, Pb, Zn and Cd;
B: at least one element selected from the group consisting of Mn, Ce, V, Fe, Co, Nb, Ta, Cr, Mo, W, Zr, Hf and Ni;
X: 0≦X≦1;
Y: 0≦Y≦2; and
Z: 1≦Z≦7.

Furthermore, a high temperature superconductor (HTSC) having a perovskite structure can also be used for the variable resistance layer 13. For example, a material expressed in a chemical composition formula of Gd_{0.7}Ca_{0.3}BaCo₂O₅₊₅ is applicable.

In addition, it is desirable that the variable resistance layer 13 has a thickness in the range of approximately 5 nm to 500 nm. For the formation of the variable resistance layer 13, the following deposition techniques can be used: pulsed laser deposition; RF sputtering; electron beam evaporation; heat evaporation; metal-organic deposition; sol-gel deposition; and metalorganic chemical vapor deposition.

[Modification 1]

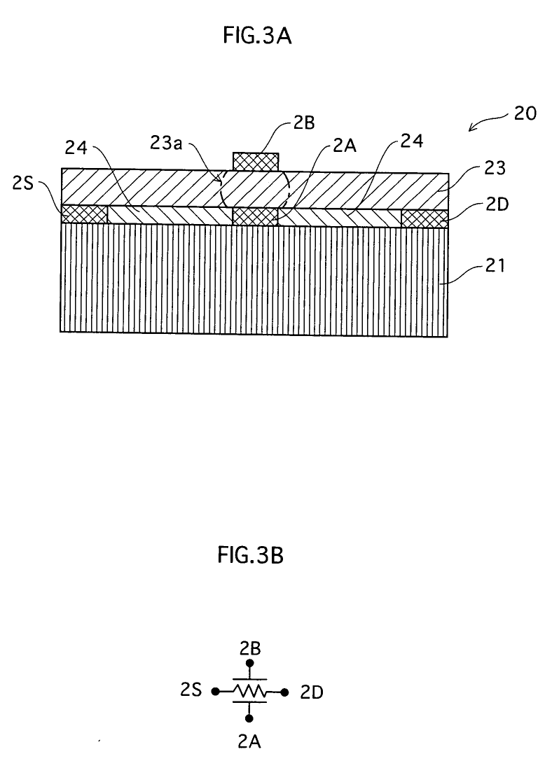

A variable resistance device 20 according to Modification 1 is described next in reference to FIGS. 3A and 3B.

As shown in FIG. 3A, the variable resistance device 20 according to the present modification differs from the above-mentioned variable resistance device 10 in the positions of 3rd and 4th electrodes 2S and 2D composing a read electrode pair, and this is a characteristic feature of the variable resistance device 20. In the variable resistance device 20, the 3rd and 4th electrodes 2S and 2D are formed on top of a substrate (e.g. a silicon substrate) 21 along with a 1st electrode 2A, and a planarizing layer (e.g. a silicon oxide layer) 24 is formed to fill the space between the 3rd and 1st electrodes 2S and 2A and between the 1st and 4th electrodes 2A and 2D. Formed on top of the electrodes 2S, 2A and 2D and the planarizing layer 24 is a variable resistance layer 23, on which only a 2nd electrode 2B is superimposed. As a constituent material of the variable resistance layer 23, the colossal magnetoresistive material, PCMO, can be applied as in the case of the above Embodiment 1.

As shown in FIG. 3B, in the variable resistance device 20 also, the four electrodes 2A, 2B, 2S and 2D are formed on the variable resistance layer 23 so that the 1st and 2nd electrodes 2A and 2B composing the control electrode pair are independent of the 3rd and 4th electrodes 2S and 2D composing the read electrode pair. In addition, also in the variable resistance device 20 according to the present modification, the 1st and 2nd electrodes 2A and 2B are positioned opposite one another, sandwiching therebetween the variable resistance layer 23 in the thickness direction, while the 3rd and 4th electrodes 2S and 2D being positioned so that a variable resistance portion 23a is formed to exist in the detection path. Thus, the variable resistance device 20 forms a four-terminal nonvolatile variable resistance device, as with the variable resistance device 10 according to Embodiment 1 above.

When the variable resistance device 20 is driven, a voltage pulse (an electric field pulse) is applied between the 1st and 2nd electrodes 2A and 2B once or several times. With the application of the voltage pulse, the electric resistance of the variable resistance portion 23a in the variable resistance layer 23 changes, which leads to altering the electric current flowing between the 3rd and 4th electrodes 2S and 2D. The electric resistance of the variable resistance portion 23a, after the change, is maintained in a nonvolatile manner. Note that the size of the variable resistance portion 23a, the electric resistance and the like are defined based on the phase state of the variable resistance layer 23, and this phase state is defined by, for example, the number of voltage pulses applied, the pulse width and the voltage value.

In the variable resistance device 20 according to Modification 1, the 3rd and 4th electrodes 2S and 2D are positioned between the substrate 21 and the variable resistance layer 23, unlike in the case of the variable resistance device 10 of the above Embodiment 1. According to the positioning of the 3rd and 4th electrodes 2S and 2D, the variable resistance device 20 promotes easier wiring inside the substrate 21 at the time when transistor elements are built in the variable resistance device 20.

Since, in the variable resistance device 20 according to the present modification also, the 1st and 2nd electrodes 2A and 2B serving as the control electrode pair and the 3rd and 4th electrodes 2S and 2D serving as the read electrode pair are arranged to be independent of each other, the flexibility in the design of an electronic circuit is high as in the case of the above variable resistance device 10. In addition, the variable resistance device 20 also adopts the positioning of the electrodes 2A, 2B, 2S and 2D above, and consequently, the electric current between the 3rd and 4th electrodes 2S and 2D can be effectively altered without changing the electric resistance of the entire variable resistance layer 23, which results in lowering the power consumption at the time when the variable resistance device 20 is driven.

[Modification 2]

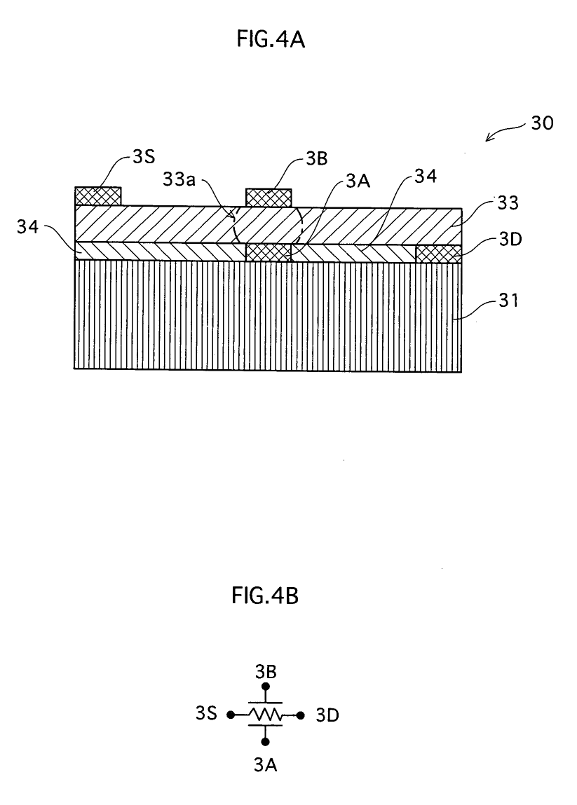

A variable resistance device 30 according to Modification 2 is described next in reference to FIGS. 4A and 4B.

As shown in FIG. 4A, the variable resistance device 30 according to the present modification has the same positioning and structure as the variable resistance device 10 of Embodiment 1 in terms of a 1st electrode 3A formed on a substrate 31, a planarizing layer 34, a variable resistance layer 33, 2nd and 3rd electrodes 3B and 3S. The variable resistance device 30 of the present modification differs from the above variable resistance device 10 in the position of a 4th electrode 3D.

In the variable resistance device 30 of the present modification, the 4th electrode 3D is positioned between the substrate 31 and the variable resistance layer 33, as with the 4th electrode 2D of Modification 1 above. In the horizontal direction in FIG. 4A, the 3rd electrode 3S is positioned to the left of the 2nd electrode 3B on the surface of the variable resistance layer 33, while the 4th electrode 3D being positioned to the right of the 1st electrode 3A between the substrate 31 and the variable resistance layer 33. Thus, by positioning the 3rd and 4th electrodes 3S and 3D of the read electrode pair this way, a read path (i.e. a detection path for electric resistance) in the variable resistance layer 33 contains therein a variable resistance portion 33a sandwiched between the 1st and 2nd electrodes 3A and 3B, as in the case of Embodiment 1 and Modification 1 described above.

The variable resistance device 30 of the present modification also forms a four-terminal nonvolatile variable resistance device with the formation of the electrodes 3A, 3B, 3S and 3D, and the equivalent circuit is as shown in FIG. 4B. In order to drive the variable resistance device 30, a voltage pulse (an electric field pulse) is applied between the 1st and 2nd electrodes 3A and 3B once or several times. Herewith, the electric resistance of the variable resistance portion 33a between the 1st and 2nd electrodes 3A and 3B is changed, which leads to altering the electric current flowing between the 3rd and 4th electrodes 3S and 3D.

The variable resistance device 30 of the present modification also has advantages of offering high flexibility in the design of an electronic circuit and lowering the power consumption when the variable resistance device 30 is driven, as with the variable resistance devices 10 and 20 of Embodiment 1 and Modification 1, respectively.

### 2. Embodiment 2

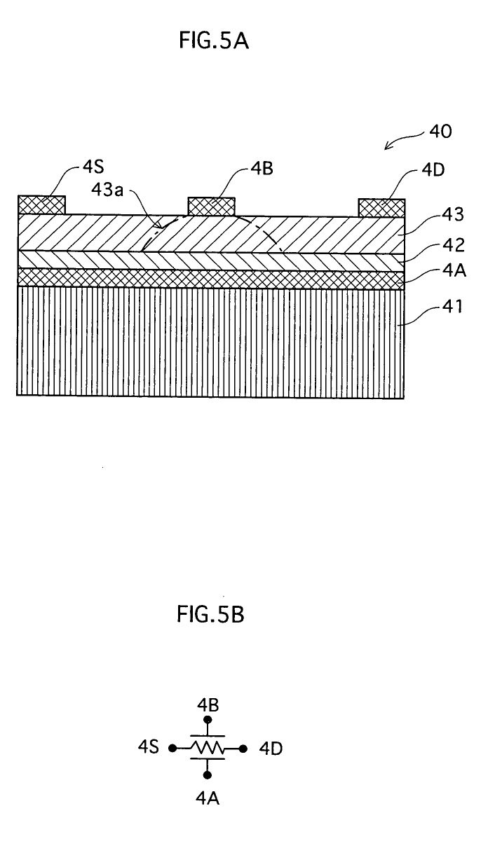

A variable resistance device 40 according to Embodiment 2 is described below in reference to FIGS. 5A and 5B.

FIG. 5A is a schematic cross section of relevant parts of the variable resistance device 40 of the present embodiment, while FIG. 5B is an equivalent circuit diagram of the variable resistance device 40.

As shown in FIG. 5A, in the variable resistance device 40 of the present embodiment, a 1st electrode 4A, a high dielectric constant layer 42, a variable resistance layer 43 made of PCMO are successively laid on a substrate (e.g. a silicon substrate) 41. In addition, three electrodes 4S, 4B and 4D independent of each other are formed on the surface of the variable resistance layer 43. These three electrodes 4S, 4B and 4D on the variable resistance layer 43 are positioned in the following order from the left in FIG. 5A: the 3rd electrode 4S, the 2nd electrode 4B, and the 4th electrode 4D. The 1st electrode 4A between the substrate 41 and the high dielectric constant layer 42 is formed along the entire extent of the variable resistance device 40 in the horizontal direction in FIG. 5A, from the position where the 3rd electrode 4S is formed to the position where the 4th electrode 4D is formed. The same applies to the high dielectric constant layer 42.

Here, the high dielectric constant layer 42 interposed between the 1st electrode 4A and the variable resistance layer 43 is made of a material expressed in a chemical composition formula of, for example, Ba_{(1-X)}Sr_{X}TiO₃.

In the viable resistance device 40 according to the present modification, the control electrode pair comprises the 1st and 2nd electrodes 4A and 4B while the read electrode pair comprising the 3rd and 4th electrodes, as in the case of Embodiment 1 and others. Within the variable resistance layer 43, a part sandwiched between the 1st and 2nd electrodes 4A and 4B and the vicinity thereof make up a variable resistance portion 43a whose electric resistance is changed as a result of a transition of the crystal condition when a voltage pulse is applied between the 1st and 2nd electrodes 4A and 4B. The variable resistance device 40 forms a four-terminal nonvolatile variable resistance device, and the equivalent circuit is as shown in FIG. 5B.

The variable resistance device 40 according to the present embodiment is characterized by a structure in which the 1st electrode 4A is positioned on the surface of the substrate 41, and the high dielectric constant layer 42 is interposed between the 1st electrode 4A and the variable resistance layer 43. The variable resistance device 40 having such a structural feature allows to separate the control electrode pair 4A and 4B from the read electrode pair 4S and 4D, as with the variable resistance device 10 according to Embodiment 1 and others, and consequently, offers high flexibility in the design of an electronic circuit. In addition, the variable resistance device 40 of the present embodiment is capable of reducing a through current flowing between the 1st and 2nd electrodes 4A and 4B when a voltage pulse (an electric field pulse) is applied to a layered structure composed of the high dielectric constant layer 42 and the variable resistance layer 43, which allows to lower the power consumption. Regarding the high dielectric constant layer 42, it may cover the entire surface of the 1st electrode 4A as shown in FIG. 5A, or alternatively, it may be interposed between the variable resistance layer 43 and the 1st electrode 4A so as to cover at least a part of the 1st electrode 4A opposing the 2nd electrode 4B.

In addition, since the variable resistance device 40 of the present embodiment uses a material expressed as Ba_{(1-X)}Sr_{X}TiO₃ having a perovskite structure to make the high dielectric constant layer 42, the high dielectric constant layer 42 exhibits a dielectric constant equivalent to or greater than (i.e. −10% or more) the dielectric constant of when the variable resistance layer 43 is in the insulating phase. This allows easy application of an electric field to the variable resistance layer 43. Although materials for making the high dielectric constant layer 42 are not confined to the above material, it is desirable that the materials respectively have a dielectric constant of at least −10% of the dielectric constant of the variable resistance layer 43 in the insulating phase. The following materials are specific examples of such materials.

<<Materials for Making the High Dielectric Constant Layer 42>>

It is desirable that, when the high dielectric constant layer 42 includes a material expressed in a chemical composition formula of A_{X}B_{Y}, A and B be defined as follows:
A: at least one element selected from the group consisting of Al, Hf, Zr, Ti, Ba, Sr, Ta, La, Si and Y; and
B: at least one element selected from the group consisting of O, N and F.

In addition, the high dielectric constant layer 42 of the variable resistance device 40 has an electric resistivity equivalent to or greater than the electric resistivity of the variable resistance layer 43 is in the insulating phase. This allows easy application of an electric field to the variable resistance layer 43, and the occurrence of leakage current in the high dielectric constant layer 42 between the 3rd and 4th electrodes 4S and 4D can be reduced when the variable resistance layer 43 is in the insulating phase.

Additionally, in the variable resistance device 40 of the present embodiment, the electric resistance of the variable resistance portion 43a in the variable resistance layer 43 is changed by applying a voltage pulse between the 1st and 2nd electrodes 4A and 4B, and the 3rd and 4th electrodes 4S and 4D are positioned so that the variable resistance portion 43a is formed to exist in the detection path formed therebetween. By adopting such a structure, the variable resistance device 40 is capable of conducting control on the electric current between the 3rd and 4th electrodes 4S and 4D in a reliable manner without the electric resistance of the entire variable resistance layer 43 being changed, which results in lowering the power consumption when the variable resistance device 40 is driven. Note that, in the variable resistance device 40 of the present embodiment, the 2nd electrode 4B—one of the two electrodes 4A and 4B composing the control electrode pair—has a smaller connection area to the variable resistance layer 43 than the 1st electrode 4A. Thus, by changing the dimensions of these electrodes of the control electrode pair to be different from each other, electric field concentration in the variable resistance layer 43 occurs when the variable resistance device 40 is driven, which leads to an increase in efficiency.

In addition, the variable resistance device 40 has the variable resistance layer 43 made of PCMO. Herewith, the change in electric resistance of the variable resistance portion 43a due to the application of a voltage pulse becomes significantly high (the ratio of electric resistance in the insulating phase to the electric resistance in the metallic phase is 100 or more), which enables reliable switching operation, as in the case of Embodiment 1 above and others.

[Modification 3]

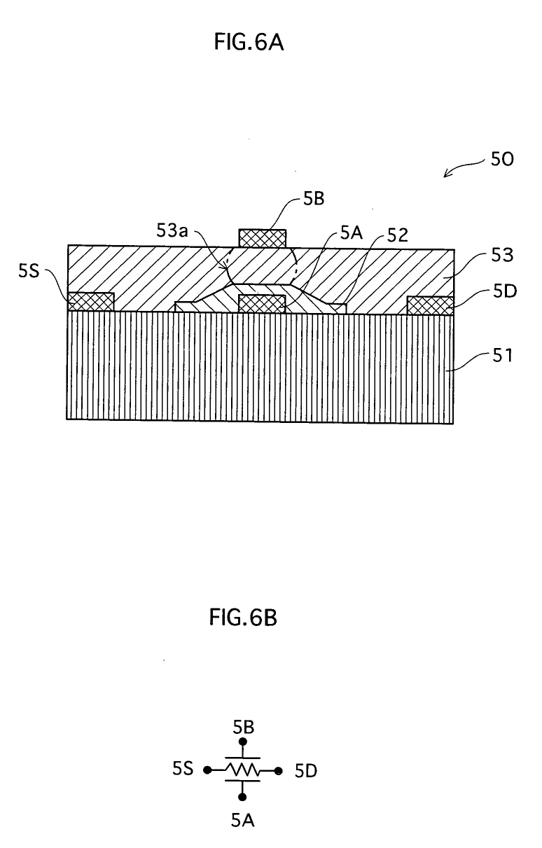

A variable resistance device 50 according to Modification 3 is described next in reference to FIGS. 6A and 6B.

As shown in FIG. 6A, in the variable resistance device 50 according to the present modification, 1st, 3rd and 4th electrodes 5A, 5S and 5D are positioned on a substrate (e.g. a silicon substrate) 51, leaving space between each other. These three electrodes 5A, 5S and 5D on the surface of the substrate 51 are positioned in the following order from the left in FIG. 6A: the 3rd electrode 5S, the 1st electrode 5A, and the 4th electrode 5D. A high dielectric constant layer 52 is formed to cover the surface of the 1st electrode 5A and its vicinity.

The high dielectric constant layer 52 is made of the same material used for the high dielectric constant layer 42 of the variable resistance device 40 according to Embodiment 2 above (e.g. a material expressed as Ba_{(1-X)}Sr_{X}TiO₃). Other than this material, materials respectively having a dielectric constant of at least −10% of the dielectric constant of the variable resistance layer 53 in the insulating phase can be used.

The variable resistance layer 53 is formed so as to cover all of the 1st, 3rd and 4th electrodes 5A, 5S and 5D, and the high dielectric constant layer 52 on the surface of the substrate 51, and a 2nd electrode 5B is formed on the variable resistance layer 53, directly above the 1st electrode 5A. Note that, although the formation of a planarizing layer is left out from the variable resistance device 50 according to the present modification as shown in FIG. 6A, a planarizing layer may be formed so as to fill the space between the 3rd electrode 5S and the high dielectric constant layer 52, or the space between the high dielectric constant layer 52 and the 4th electrode 5D.

Regarding the variable resistance device 50 according to the present modification, the 1st and 2nd electrodes 5A and 5B compose the control electrode pair while the 3rd and 4th electrodes 5S and 5D composing the read electrode pair, as in the case of Embodiment 2 above and others. The positions of the respective electrodes 5A, 5B, 5S and 5D are the same in the case of the variable resistance device 20 according to Modification 1 above. According to such a structure, the variable resistance device 50 forms a four-terminal nonvolatile variable resistance device, as an equivalent circuit shown in FIG. 6B. When the variable resistance device 50 is driven, a voltage pulse (an electric field pulse) is applied between the 1st and 2nd electrodes 5A and 5B once or several times. As a result, the electric resistance of a variable resistance portion 53a is changed, and consequently the electric current flowing between the 3rd and 4th electrodes 5S and 5D composing the read electrode pair is altered.

The variable resistance device 50 of the present modification has advantages of, such as, offering high flexibility in the design of an electric circuit and lowering the power consumption. Furthermore, in the variable resistance device 50, the interposition of the high dielectric constant layer 52 allows easy application of an electric field to the variable resistance layer 53, as in the case of the variable resistance device 40 according to Embodiment 2. Besides, the occurrence of leakage current between the 3rd and 4th electrodes 5S and 5D can be reduced when the variable resistance layer 53 is in the insulating phase.

[Modification 4]

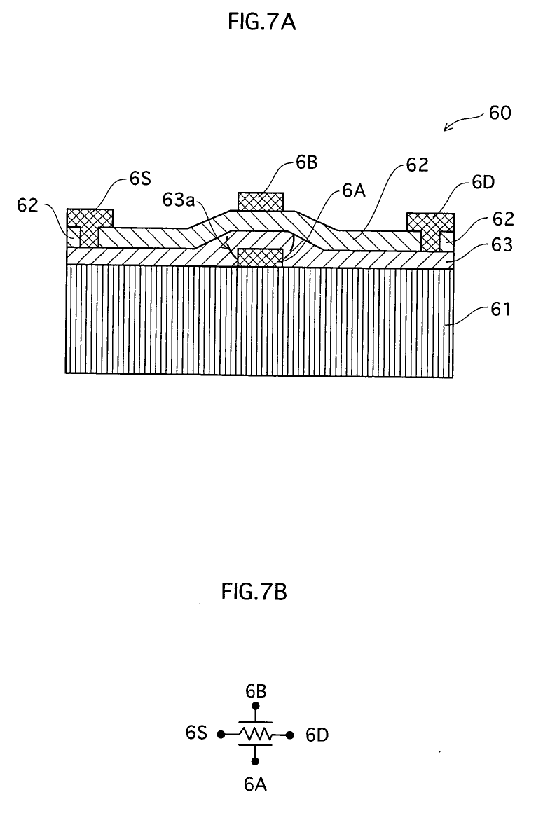

A variable resistance device 60 according to Modification 4 is described next in reference to FIGS. 7A and 7B.

As shown in FIG. 7A, in the variable resistance device 60 according to the present modification, a 1st electrode 6A is positioned on the surface of a substrate (e.g. a silicon substrate) 61, and a variable resistance layer 63 is formed to cover the entire surface of the substrate 61 with the 1st electrode 6A being positioned thereon, as in the case of the variable resistance device 10 according to Embodiment 1 above. Formed on the surface of the variable resistance layer 63 is a high dielectric constant layer 62, on a part of which a 2nd electrode 6B is formed. The 2nd electrode 6B is formed directly above the 1st electrode 6A in a manner that the 1st and 2nd electrodes 6A and 6B sandwich therebetween the variable resistance layer 63 and high dielectric constant layer 62 in the thickness direction.

Formed on the surface of the high dielectric constant layer 62 are 3rd and 4th electrodes 6S and 6D, each of which is connected to the variable resistance layer 63 via a contact plug. In the variable resistance device 60 according to the present modification, 1st, 2nd, 3rd and 4th electrodes 6A, 6B, 6S and 6D are formed to be independent of each other, and the equivalent circuit is as shown in FIG. 7B. As shown in the figure, in the variable resistance device 60 of the present modification also, the 1st and 2nd electrodes 6A and 6B compose the control electrode pair while the 3rd and 4th electrodes 6S and 6D composing the read electrode pair.

The variable resistance layer 63 is made of a colossal magnetoresistive material having a perovskite structure, as in the case of Embodiment 2 above. PCMO is a specific example of constituent materials of the variable resistance layer 63 as with above. In addition, the high dielectric constant layer 62 is made of a material expressed in a chemical composition formula of, for example, Ba_{(1-X)}Sr_{X}TiO₃, as in the case of Embodiment 2 above.

As has been described, the variable resistance device 60 also forms a four-terminal nonvolatile variable resistance device.

When the variable resistance device 60 is driven, a voltage pulse (an electric field pulse) is applied between the 1st and 2nd electrodes 6A and 6B once or several times. As a result, the electric resistance of a variable resistance portion 63a in the variable resistance layer 63 is changed, and consequently, the electric current flowing between the 3rd and 4th electrodes 6S and 6D composing the read electrode pair is altered.

Exhibiting the same advantages as the variable resistance device 40 according to Embodiment 2 above, the variable resistance device 60 of the present modification also reduces the occurrence of surface leakage current more efficiently than the variable resistance device 40 does. In addition, the space between the 2nd and 3rd electrodes 6B and 6S and between the 2nd and 4th electrodes 6B and 6D can be made smaller since the variable resistance device 60 has adopted a structure in which the 3rd and 4th electrodes 6S and 6D are respectively connected to the variable resistance layer 63 via contact plugs, and the high dielectric constant layer 62 is laid on top of the variable resistance layer 63. Accordingly, the variable resistance device 60 of the present modification provides benefit in terms of downsizing.

[Modification 5]

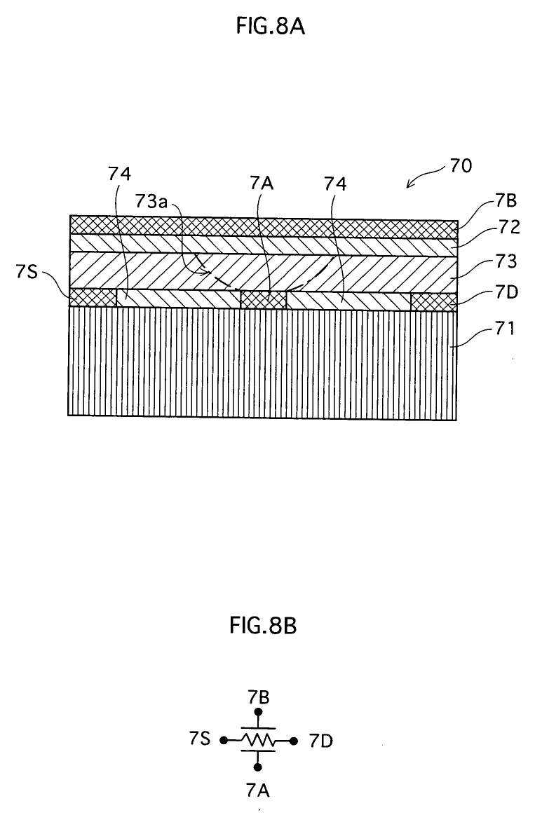

A variable resistance device 70 according to Modification 5 is described next in reference to FIGS. 8A and 8B.

As shown in FIG. 8A, in the variable resistance device 70 according to the present modification, 1st, 3rd and 4th electrodes 7A, 7S and 7D are formed on the surface of a substrate (e.g. a silicon substrate) 71, and a planarizing layer (e.g. a silicon oxide layer) 74 is formed to fill space between each electrode 7A, 7S and 7D. These electrodes 7A, 7S and 7D are positioned in the order of the 3rd, 1st and 4th, 7S, 7A and 7D, from the left to right in FIG. 8A.

Laid on top of the electrodes 7A, 7S and 7D and the planarizing layer 74 is the variable resistance layer 73 made of PCMO, on which a high dielectric constant layer 72 and then a 2nd electrode 7B are superimposed.

As shown in FIG. 8B, the 1st and 2nd electrodes 7A and 7B compose the control electrode pair while the 3rd and 4th electrodes 7S and 7D composing the read electrode pair, and the variable resistance device 70 forms a four-terminal nonvolatile variable resistance device, as with the variable resistance device 40 according to Embodiment 2 above and others.

Note that, in the variable resistance device 70 of the present modification, the high dielectric constant layer 72 can be formed by using the same constituent material of the high dielectric constant layer 42 of the variable resistance device 40 according to Embodiment 2.

As shown in FIG. 8A, a variable resistance portion 73a in the variable resistance layer 73 is formed in a part sandwiched between the 1st and 2nd electrodes 7A and 7B and the vicinity thereof. Since the dimensions of the 1st electrode 7A are set smaller than those of the 2nd electrode 7B, electric field concentration can be realized when a voltage pulse is applied between the electrodes 7A and 7B.

The variable resistance device 70 according to the present modification offers high flexibility in the design of an electronic circuit and lowers the power consumption, as with the variable resistance device 40 according to Embodiment 2 above. Since the high dielectric constant layer 72 is also interposed in the variable resistance device 70, the occurrence of leakage current in the high dielectric constant layer 72 between the 3rd and 4th electrodes 7S and 7D can be reduced when the variable resistance layer 73 is in the insulating phase.

Furthermore, the variable resistance device 70 of the present modification shows high tolerance when exposed to a reduction atmosphere during, for instance, the production process because the 2nd electrode 7B is formed to cover the entire top surface of the variable resistance device 70.

[Modification 6]

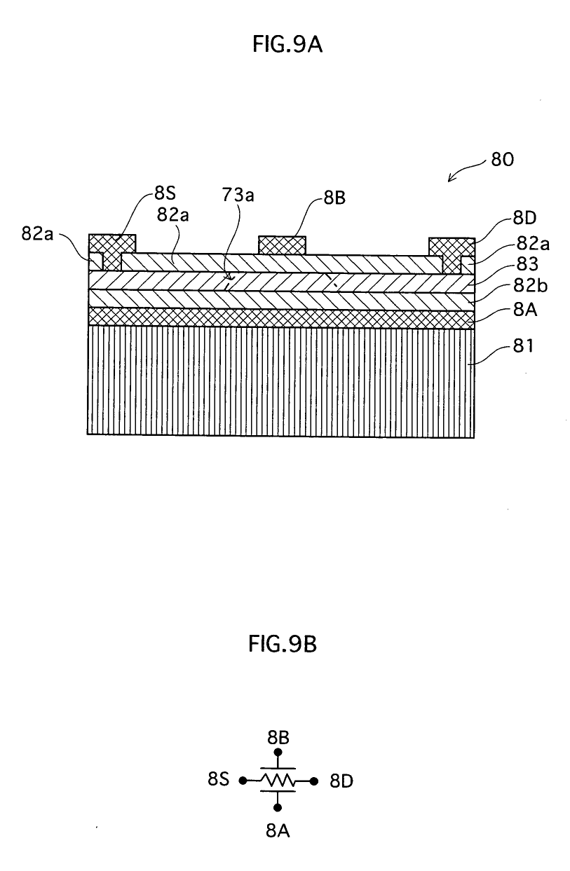

A variable resistance device 80 according to Modification 6 is described next in reference to FIGS. 9A and 9B.

As shown in FIG. 9A, the variable resistance device 80 has a layered structure in which a 1st electrode 8A is formed on the entire surface of a substrate (e.g. a silicon substrate) 81, and a 1st high dielectric constant layer 82b, a variable resistance layer 83 made of PCMO, and a 2nd high dielectric constant layer 82a are successively laid on the 1st electrode 8A. In addition, 2nd, 3rd and 4th electrodes 8B, 8S and 8D are formed on the surface of the 2nd high dielectric constant layer 82a, leaving space between each other. Of the electrodes, the 3rd and 4th electrodes 8S and 8D are respectively connected to the variable resistance layer 83 via contact plugs.

Both 1st and 2nd high dielectric constant layers 82a and 82b are made of a material expressed in a chemical composition formula of Ba_{(1-X)}Sr_{X}TiO₃.

In the variable resistance device 80 according to the present embodiment also, the four electrodes 8A, 8B, 8S and 8D are arranged to be independent of each other, forming a four-terminal nonvolatile variable resistance device as shown in FIG. 9B. A variable resistance portion 83a is formed, within the variable resistance layer 83, at a part sandwiched between the 1st and 2nd electrodes 8A and 8B and the vicinity thereof. Due to a difference in the connection areas to the variable resistance layer 83 between the 1st and 2nd electrodes 8A and 8B, the variable resistance portion 83a is capable of inducing electric field concentration at the application of a voltage pulse, as in the case of Modification 5 above.

The variable resistance device 80 of the present modification also offers high flexibility in the design of an electronic circuit and lowers the power consumption when the variable resistance device 80 is driven. Additionally, in the variable resistance device 80, the space among the three electrodes 8S, 8B and 8D on the surface of the 2nd high dielectric constant layer 82a can be set smaller, as with the variable resistance device 60 according to Modification 4 above.

[Modification 7]

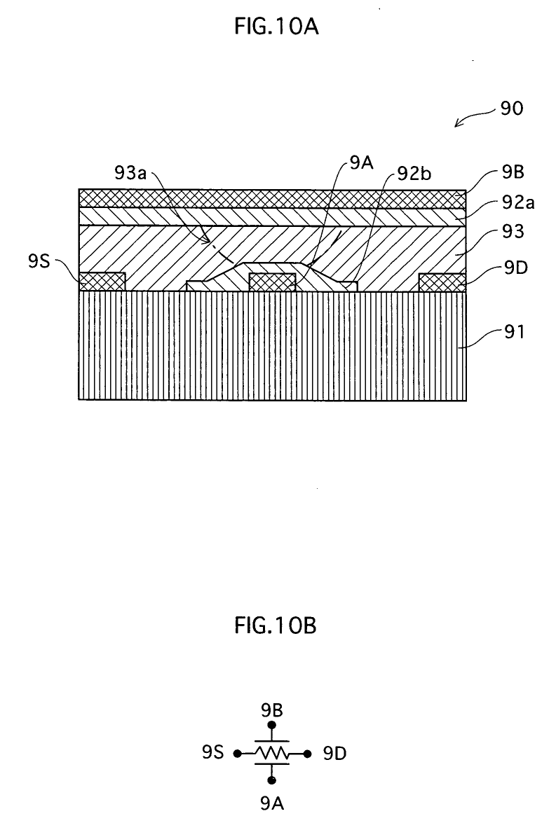

A variable resistance device 90 according to Modification 7 is described next in reference to FIGS. 10A and 10B.

As shown in FIG. 10A, the variable resistance device 90 according to the present modification has a structure similar to the variable resistance device 70 of Modification 5 above, differing in having no planarizing layer formed and having a 2nd high dielectric constant layer 92b interposed between a 1st electrode 9A and a variable resistance layer 93.

Specifically speaking, in the variable resistance device 90, 3rd, 1st and 4th electrodes 9S, 9A and 9D are formed on the surface of a substrate (e.g. a silicon substrate) 91, leaving space between each other, and the 2nd high dielectric constant layer 92b is formed to cover the 1st high electrode 9A. Then, the variable resistance layer 93, the 1st high dielectric constant layer 92a, and the 2nd electrode 9B are formed in layers to cover the 2nd high dielectric constant layer 92b and the electrodes 9S, 9A and 9D on the substrate 91.

The variable resistance layer 93 and the 1st and 2nd high dielectric constant layers 92a and 92b, can be formed, employing the same materials used for the variable resistance device 80 according to Modification 6 above.

The 1st and 2nd electrodes 9A and 9B compose the control electrode pair for applying an electric field to the variable resistance layer 93, while the 3rd and 4th electrodes 9S and 9D compose the read electrode pair for detecting the electric resistance of a variable resistance portion 93a in the variable resistance layer 93. In addition, the 1st and 2nd electrodes 9A and 9B are positioned opposite from each other, sandwiching therebetween the variable resistance layer 93 in the thickness direction. On the other hand, the 3rd and 4th electrodes 9S and 9D are respectively positioned on each side of the 1st electrode 9A within the interfacial region between the substrate 91 and the variable resistance layer 93.

The variable resistance device 90 having such a structure forms a four-terminal nonvolatile variable resistance device (see FIG. 10B), as with the variable resistance devices 40 and 80 of above Embodiment 2 and Modification 6, respectively, and has advantages of offering high flexibility in the design of an electronic circuit and lowering the power consumption when the variable resistance device 90 is driven. In addition, since the variable resistance device 90 has adopted a structure in which the 1st high dielectric constant layer 92a is interposed between the viable resistance layer 93 and the 2nd electrode 9B while the 2nd high dielectric constant layer 92b being interposed between the variable resistance layer 93 and the 1st electrode 9A. Herewith, the occurrence of leakage current between the 3rd and 4th electrodes 9S and 9D can be reduced when the variable resistance layer 93 is in the insulating phase.

Furthermore, the variable resistance device 90 shows high tolerance when exposed to a reduction atmosphere during, for instance, the production process because the entire top surface of the variable resistance device 90 is covered by the 2nd electrode 9B, as with the variable resistance device 70 according to Modification 5 above.

[Modification 8]

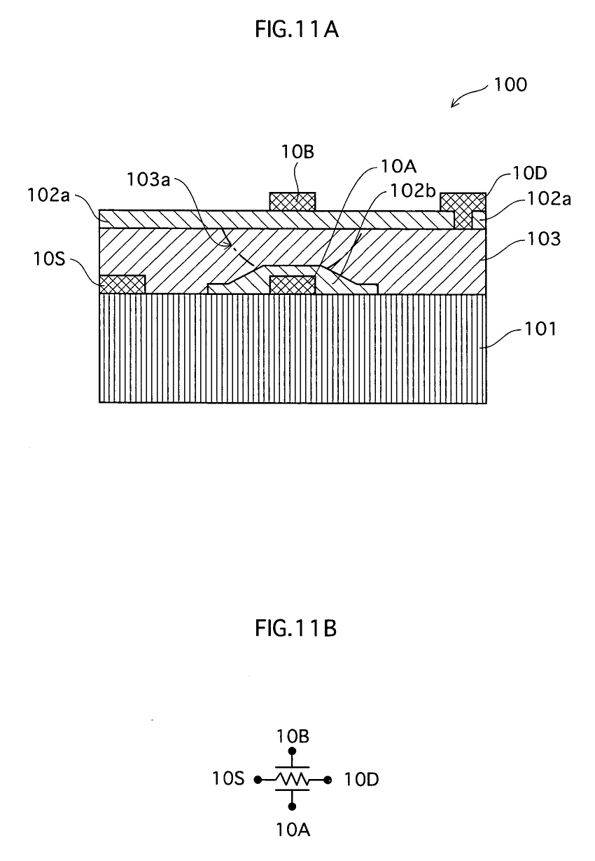

A variable resistance device 100 according to Modification 8 is described next in reference to FIGS. 11A and 11B.

As shown in FIG. 11A, the variable resistance device 100 of the present modification has the same structure as the variable resistance device 90 according to Modification 7 above, except for the structure of 2nd and 4th electrodes 10B and 10D. The following gives an account of the variable resistance device 100, focusing on the difference from the variable resistance device 90 of Modification 7 above.

In the variable resistance device 100, the 2nd electrode 10B is formed on a part of the surface of a 1st high dielectric constant layer 102a, or more specifically speaking, the 2nd electrode 10B is formed to oppose a 1st electrode 10A, sandwiching therebetween a 2nd high dielectric constant layer 102b and a variable resistance layer 103. In addition, the 4th electrode 10D of the variable resistance device 100 is formed on the 1st high dielectric constant layer 102a, and connected to the variable resistance layer 103 via a contact plug.

Regarding the variable resistance device 100, in the horizontal direction in FIG. 11A, the 4th electrode 10D—one electrode composing the read electrode pair—formed on the 1st high dielectric constant layer 102a is located diagonally opposite to a 3rd electrode 10S across from a variable resistance portion 103a formed between the 1st and 2nd electrodes 10A and 10B. By adopting such a structure, the electric resistance detection path between the 3rd and 4th electrodes 10S and 10D includes therein the variable resistance portion 103a.

As has been described, the variable resistance device 100 of the present modification also forms a four-terminal nonvolatile variable resistance device, as shown in FIG. 11B. The variable resistance device 100 having this structure has advantages of offering high flexibility in the design of an electronic circuit and lowering the power consumption when the variable resistance device 100 is driven, as in the case of Embodiment 2 above and others. Additionally, since the variable resistance device 100 has adopted a structure in which the 2nd high dielectric constant layer 102b is interposed between the variable resistance layer 103 and the 1st electrode 10A while the 1st high dielectric constant layer 102a being interposed between the variable resistance layer 103 and the 2nd electrode 10B, the occurrence of leakage current between the 3rd and 4th electrodes 10S and 10D can be reduced when the variable resistance layer 103 is in the insulating phase.

As to the formation of the variable resistance device 100 according to the present modification, the same, various materials used in Embodiment 2 and each modification above can be applied. Furthermore, the materials used and the compositional form of each element can also be changed accordingly.

### 3. Embodiment 3

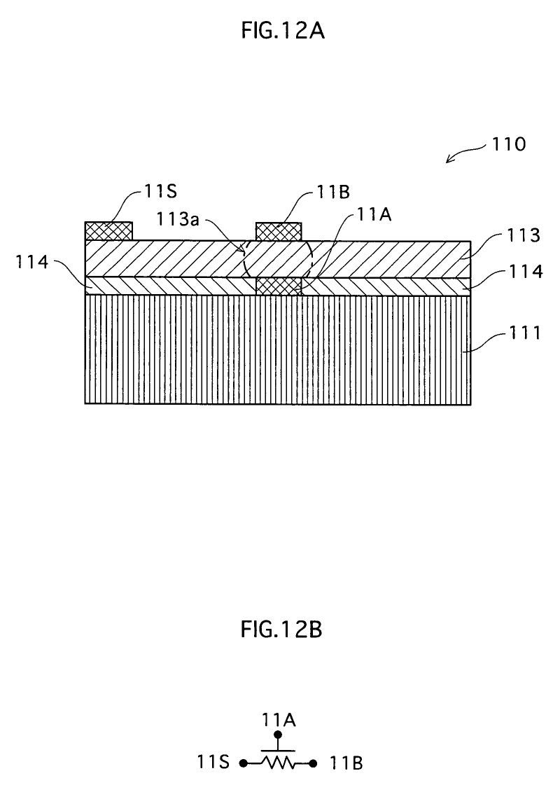

The following gives an account of a variable resistance device 110 according to Embodiment 3 with the aid of FIGS. 12A and 12B.

As shown in FIG. 12A, the variable resistance device 110 according to the present embodiment is structurally characterized by its being a three-terminal device, while the respective variable resistance devices 10 to 100 of Embodiments 1 and 2 and Modifications 1 to 8 form four-terminal devices. The variable resistance device 110 has a layered structure in which: a 1st electrode 11A and a planarizing layer (e.g. a silicon oxide layer) 114 is formed on the substrate (e.g. a silicon substrate) 111; further a variable resistance layer 113 made, for example, of PCMO is formed on the 1st electrode 11A and the planarizing layer 114; and then 2nd and 3rd electrodes 11B and 11S are formed on the variable resistance layer 113.

Of the three electrodes 11A, 11B and 11S of the variable resistance device 110, the 1st and 2nd electrodes 11A and 11B compose the control electrode pair for applying an electric field to the variable resistance layer 113, and are positioned opposite one another so as to sandwich therebetween the variable resistance layer 113 in the thickness direction. The remaining electrode of the three, or the 3rd electrode 11S, composes the read electrode pair for detecting the electric resistance of a variable resistance portion 113a together with the 2nd electrode 11B formed on the same surface of the variable resistance layer 113. That is, in the variable resistance device 110 of the present embodiment, the 2nd electrode 11B, which is one of the control electrode pair, also serves as one electrode of the read electrode pair, unlike in the case of Embodiments 1 and 2 above.

Thus, the variable resistance device 110 of the present embodiment forms a three-terminal nonvolatile variable resistance device as shown in FIG. 12B.

When the variable resistance device 110 is driven, a voltage pulse (an electric field pulse) is applied between the 1st and 2nd electrodes 11A and 11B once or several times. With the application of the voltage pulse, the electric resistance of the variable resistance portion 113a sandwiched between the 1st and 2nd electrodes 11A and 11B changes. This causes a change in an electric current flowing between the read electrode pair, i.e. the 2nd and 3rd electrodes 11B and 11S, arranged so that the variable resistance portion 113a is formed to exist in a part of the electric resistance detection path. In the variable resistance device 110 of the present embodiment also, the variable resistance layer 113 is formed by using the same PCMO as in the case of Embodiments 1 and 2 above, and therefore, the change in electric resistance of the variable resistance portion 113a due to the application of a voltage pulse becomes significantly high (the ratio of the electric resistance in the insulating phase to the electric resistance in the metallic phase is 100 or more), which enables reliable switching operation. By controlling application conditions of the voltage pulse (e.g. the number of voltage pulses applied, the pulse width and the voltage value), the crystal condition of the variable resistance portion 113a goes from the metallic phase to the insulating phase, or to a complex phase in which the metallic and insulating phases coexist. Herewith, the variable resistance device 110 can be an effective constituent part of an analog signal processing circuit.

The variable resistance device 110 of the present embodiment has a three-terminal configuration, and the control electrode pair comprising the 1st and 2nd electrodes 11A and 11B and the read electrode pair comprising the 2nd and 3rd electrodes 11B and 11S are respectively established as different systems. Therefore, the variable resistance device 110 of the present embodiment also has advantages of separating the control on the application of a voltage pulse from the data path in a reliable manner and offering high flexibility in the design of an electronic circuit. Furthermore, as compared with the variable resistance devices 10 to 100 according to Embodiments 1 and 2 and Modifications 1 to 8 above, the variable resistance device 110 of the present embodiment does not have a 4th electrode, and thus the number of electrodes to be formed decreases by one, which results in simplifying the structure of the device itself.

In the variable resistance device 110, although the read electrode pair is composed of the 2nd and 3rd electrodes 11B and 11S, the variable resistance portion 113a exists in the electric resistance detection path formed therebetween. Therefore, the variable resistance device 110 is also capable of controlling the electric current between the 2nd and 3rd electrodes 11B and 11S without changing the electric resistance of the entire variable resistance layer 113, which allows to lower the power consumption.

[Modification 9]

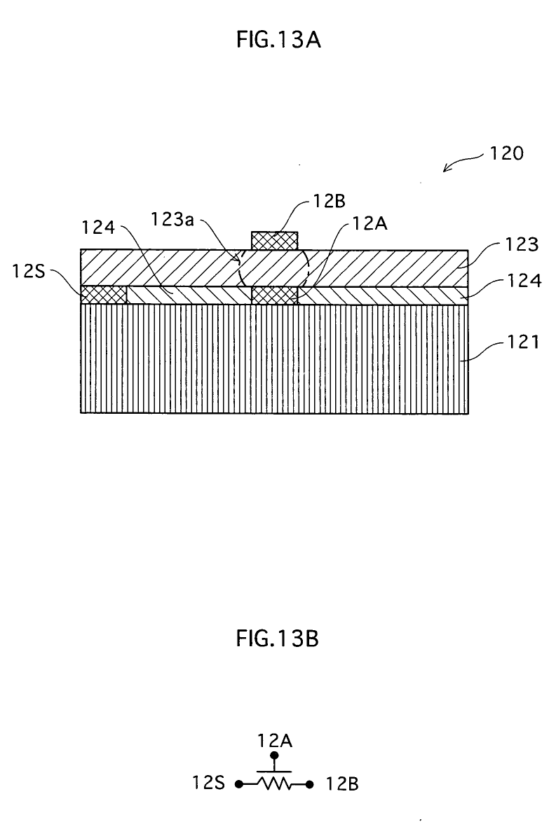

A structure of a variable resistance device 120 according to Modification 9 is described next with the aid of FIGS. 13A and 13B.

As shown in FIG. 13A, the variable resistance device 120 according to the present modification has a structure different from the variable resistance device 110 of Embodiment 3 above in regard to the position of a 3rd electrode 12S-one electrode composing the read electrode pair. Namely, in the variable resistance device 120 of the present modification, the 3rd electrode 12S is formed on the surface of a substrate 121 on which a 1st electrode 12A is also formed, while a 2nd electrode 12B is formed on the surface of a variable resistance layer 123.

As to the variable resistance device 120, the same materials used for the variable resistance device 110 of Embodiment 3 above can be employed for the formation of the substrate 121, the variable resistance layer 123 and the like.

The variable resistance device 120 having such a structure also forms a three-terminal nonvolatile variable resistance device, as shown in FIG. 13B.

Additionally, as with the variable resistance device 110 of Embodiment 3 above, the variable resistance device 120 of the present modification also has advantages of separating the control on the application of a voltage pulse from the data path in a reliable manner and offering high flexibility in the design of an electronic circuit, as well as advantages of offering high flexibility in the design of an electronic circuit and lowering the power consumption since the respective electrodes 12A, 12B and 12S are arranged so that a variable resistance portion 123a is formed to exist in its electric resistance detection path.

Furthermore, as compared with the variable resistance devices 10 to 100 according to Embodiments 1 and 2 and Modifications 1 to 8 above, the variable resistance device 120 has a simplified structure since it does not have a 4th electrode equivalent to 1D to 10D in those embodiments and modifications while the 2nd electrode 12B serving also as one electrode of the read electrode pair.

[Modification 10]

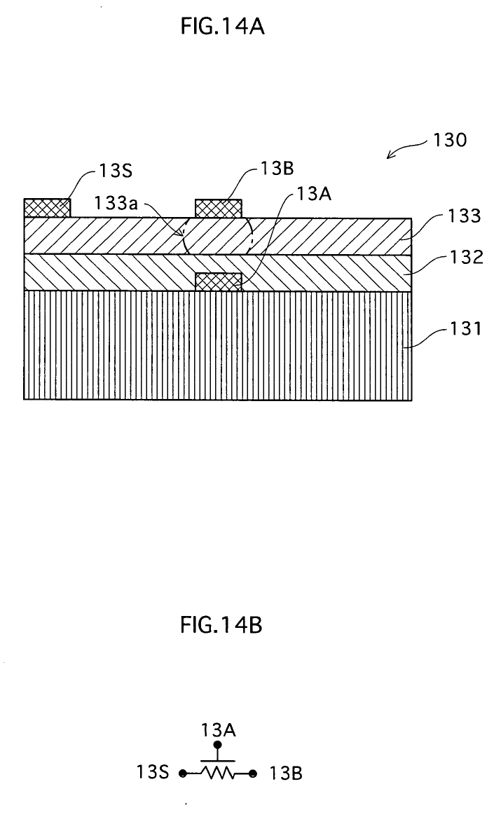

A structure of a variable resistance device 130 according to Modification 10 is described next with the aid of FIGS. 14A and 14B.

As shown in FIG. 14A, the variable resistance device 130 according to the present modification structurally differs from the variable resistance device 110 of Embodiment 3 above in not having a planarizing layer but having a high dielectric constant layer 132. That is, in the variable resistance device 130, a 1st electrode 13A is formed on the surface of the substrate (e.g. a silicon substrate) 131, the high dielectric constant layer 132 and a variable resistance layer 133 are successively formed in layers to cover the 1st electrode 13A, and 2nd and 3rd electrodes 13B and 13S are formed on the surface of the variable resistance layer 133. Here, the same materials used for the high dielectric constant layer 42 and variable resistance layer 43 according to Embodiment 2 can be respectively employed for the formation of the high dielectric constant layer 132 and variable resistance layer 133.

As shown in FIG. 14B, the variable resistance device 130 has the 1st and 2nd electrodes 13A and 13B composing the control electrode pair and the 2nd and 3rd electrodes 13B and 13S composing the read electrode pair, and thus forms a three-terminal nonvolatile variable resistance device. In addition, in the variable resistance device 130 also, a variable resistance portion 133a is formed to exist in the electric resistance detection path between the 2nd and 3rd electrodes 13B and 13S, as with the variable resistance devices 110 and 120 according to Embodiment 3 and Modification 9 above.

The variable resistance device 130 with such a structure also has advantages of: offers high flexibility in the design of an electronic circuit; a reduction in the power consumption; and a simplified structure of the device itself.

The variable resistance device 130 of the present modification is formed so that the high dielectric constant layer 132 covers the entire surface of the substrate 131 with the 1st electrode 13A positioned thereon. However, covering at least the surface of the 1st electrode 13A suffices for the purpose of achieving a reduction in the occurrence of leakage current, and therefore, the dielectric constant layer 132 does not necessarily have to cover the entire surface of the substrate 131. A modification in regard to the configuration of such a high dielectric constant layer is described next.

[Modification 11]

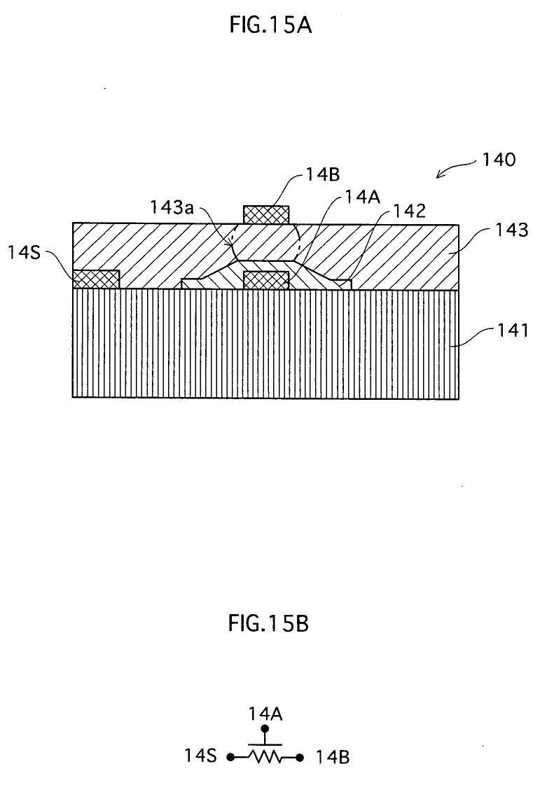

A variable resistance device 140 according to Modification 11 is described next with the aid of FIGS. 15A and 15B.

As shown in FIG. 15A, the variable resistance device 140 according to the present modification differs from the variable resistance device 130 of Modification 10 above in the configuration of a high dielectric constant layer 142. Specifically speaking, 1st and 3rd electrodes 14A and 14S are formed on the surface of a substrate (e.g. a silicon substrate) 141; the high dielectric constant layer (made, for example, of a material expressed in a chemical composition formula of Ba_{(1-X)}Sr_{X}TiO₃) 142 is formed to cover the surface of the 1st electrode 14A; a variable resistance layer 143 made of PCMO is formed to entirely cover the 3rd electrode 14S and the high dielectric constant layer 142; and then a 2nd electrode 14B is formed on a part of the top surface of the variable resistance layer 143.

As to the variable resistance device 140 of the present modification also, the 1st and 2nd electrodes 14A and 14B compose the control electrode pair, while the 2nd electrode 14B—one of the two composing the control electrode pair—and the 3rd electrode 14S compose the read electrode pair. A variable resistance portion 143a is formed in a part of the variable resistance layer 143, which is sandwiched between the 1st and 2nd electrodes 14A and 14B, and the read electrode pair is arranged so that the variable resistance portion 143a is formed to exist within the path. Thus, the variable resistance device 140 according to the present modification also forms a three-terminal nonvolatile variable resistance device as shown in FIG. 15B.

As with the variable resistance device 130 according to Modification 10 above, the variable resistance device 140 of the present modification has advantages of: high flexibility in the design of an electronic circuit; a reduction in the power consumption; a simplified structure of the device itself; and a reduction in the occurrence of leakage current when the variable resistance layer 143 is in the insulating phase.

[Modification 12]

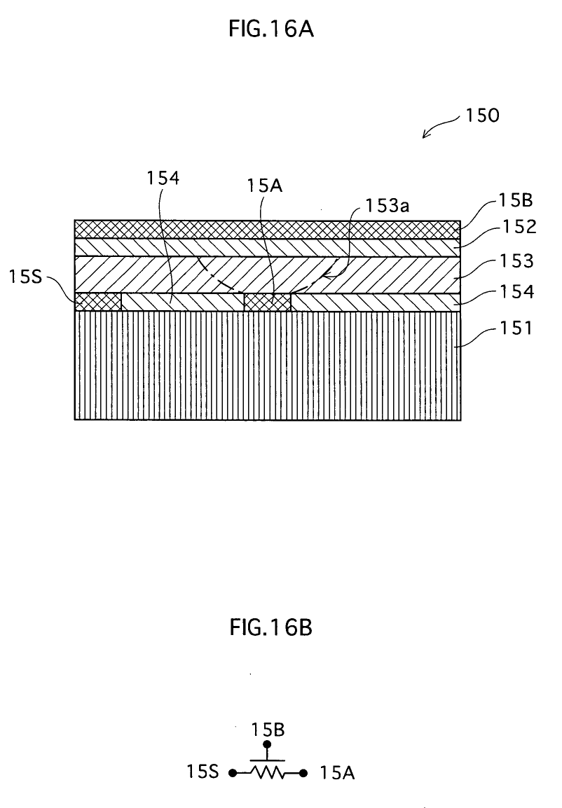

A structure of a variable resistance device 150 according to Modification 12 is described next with the aid of FIGS. 16A and 16B.

As shown in FIG. 16A, the variable resistance device 150 according to the present modification structurally differs from the variable resistance device 120 of Modification 9 in the configuration of a 2nd electrode 15B and the interposition of a high dielectric constant layer 152. The following gives an account of the variable resistance device 150 of the present modification, focusing on the differences from the case of Modification 9 above.

As shown in FIG. 16A, in the variable resistance device 150, 1st and 3rd electrodes 15A and 15S, a planarizing layer 154, and a variable resistance layer 153 are formed on the surface of a substrate 151 in a similar configuration to the variable resistance device 120 according to Modification 9. Additionally, in the variable resistance device 150, the high dielectric constant layer 152 and the 2nd electrode 15B are successively laid on the entire surface of the variable resistance layer 153. Materials used for forming the substrate 151, the variable resistance layer 153, the high dielectric constant layer 152 and the like are the same as those in Embodiment 3 and Modification 9 above.

As shown in FIG. 16B, the variable resistance device 150 has the 1st and 2nd electrodes 15A and 15B composing the control electrode pair and the 1st and 3rd electrodes 15A and 15S composing the read electrode pair, and thus forms a three-terminal nonvolatile variable resistance device. The 1st and 2nd electrodes 15A and 15B are positioned opposite one another, sandwiching therebetween the variable resistance layer 153 in the thickness direction. Of them, the 1st electrode 15A also serves as one of the read electrode pair.

The 3rd electrode 15S is positioned on the surface of the substrate 151, next to the 1st electrode 15A with space therebetween, and the planarizing layer 154 is interposed in the space. Then, at least a part of the region sandwiched between the 1st and 2nd electrodes 15A and 15B has a layered structure comprising the variable resistance layer 153 and the high dielectric constant layer 152.

The variable resistance device 150 with such a structure has advantages of offering high flexibility in the design of an electronic circuit and lowering the power consumption, as with the variable resistance device 110 according Embodiment 3. In addition, since having a three-terminal configuration, the variable resistance device 150 also has an advantage of a simplified structure of the device itself. Furthermore, the variable resistance device 150 also has an advantage of reducing the occurrence of leakage current when the variable resistance layer 153 is in the insulating phase, as in the case of Modification 11 above.

[Modification 13]

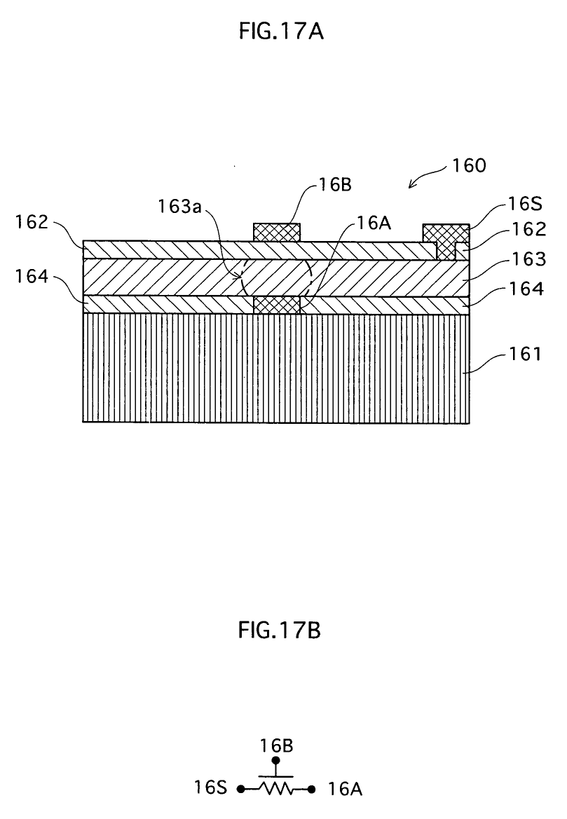

A structure of a variable resistance device 160 according to Modification 13 is described next with the aid of FIGS. 17A and 17B.

As shown in FIG. 17A, the variable resistance device 160 according to the present modification differs from the variable resistance device 150 of Modification 12 above in the configuration of 2nd and 3rd electrodes 16B and 16S. Specifically speaking, a 1st electrode 16A, a planarizing layer 164, a variable resistance layer 163 and a high dielectric constant layer 162 are successively laid on the surface of a substrate 161. Then, the 2nd and 3rd electrodes 16B and 16S are formed, apart from each other, on the surface of the high dielectric constant layer 162. Of them, the 3rd electrode 16S is positioned to the right of the 2nd electrode 16B in the horizontal direction in FIG. 17A. According to the positioning of the 3rd electrode 16S, a variable resistance portion 163a formed in a part of the variable resistance layer 163, which is sandwiched between the 1st and 2nd electrodes 16A and 16B, exists in the electric resistance detection path between the 1st and 3rd electrodes 16A and 16S. Additionally, the 3rd electrode 16S is connected to the variable resistance layer 163 via a contact plug formed by penetrating the high dielectric constant layer 162.

The variable resistance device 160 having such a structure forms a three-terminal nonvolatile variable resistance device in which the 1st and 2nd electrodes 16A and 16B compose the control electrode pair while the 1st and 3rd electrodes 16A and 16S composing the read electrode pair.

The variable resistance device 160 with such a structure has advantages of offering high flexibility in the design of an electronic circuit, lowering the power consumption, and furthermore reducing the occurrence of leakage current when the variable resistance layer 163 is in the insulating phase, as with the variable resistance device 150 according to Modification 12 above. In addition, since having the three-terminal configuration, the variable resistance device 160 is capable of simplifying the structure of the device itself, and also provides benefit in terms of the downsizing of the device owing that the 3rd electrode 16S is connected to the variable resistive layer 163 via a contact plug.

### 4. Embodiment 4

The following gives an account of a semiconductor apparatus applying the above variable resistance device 10 to 160, with the aid of an example.

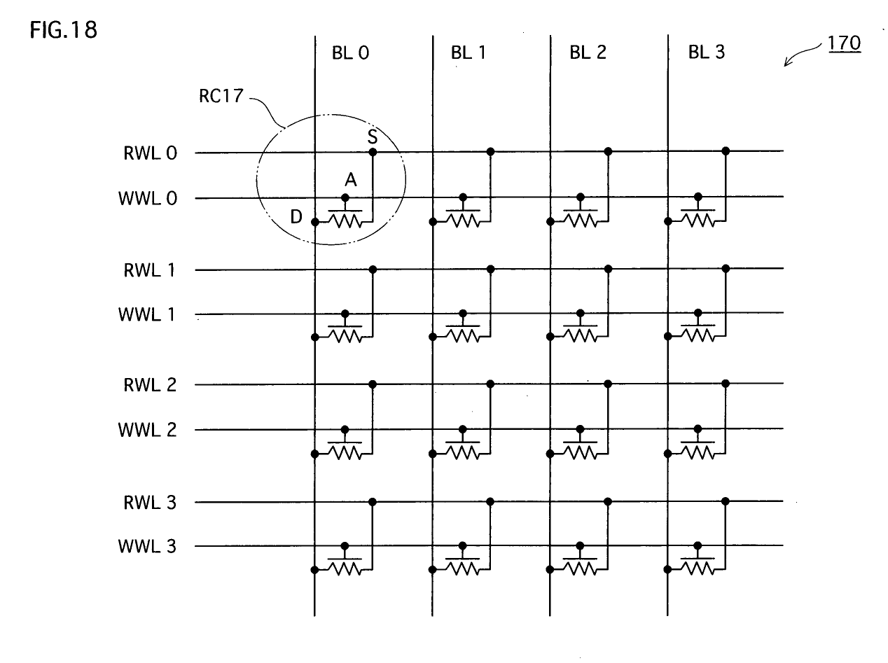

A semiconductor apparatus 170 according to Embodiment 4 is described next with the use of FIG. 18. Note that FIG. 18 shows part of a memory array structure of the semiconductor apparatus 170.

As shown in FIG. 18, in the semiconductor apparatus 170 according to the present embodiment, read-word lines RWL0 to RWL3 and write-word lines WWL0 to WWL3 are alternately arranged, running parallel to each other, and bit lines BL0 to BL3 are arranged in a direction intersecting with these word lines RWL0 to RWL3 and WWL0 to WWL3. Nonvolatile variable resistance devices RC17 are respectively formed at intersections of the bit lines BL0 to BL3 and the read—and write-word lines RWL0 to RWL3 and WWL0 to WWL3.

Used as the nonvolatile variable resistance devices RC17 at the intersections are the variable resistance devices 110 to 160 according to Embodiment 3 and Modifications 9 to 13 above. Here, the write-word lines WWL0 to WWL3 are constructed by mutually connecting terminals A in the row direction, each of which is connected to one electrode of the control electrode pair, while the read-word lines RWL0 to RWL3 being constructed by mutually connecting terminals S in the row direction, each of which is connected to one electrode of the read electrode pair. Additionally, the bit lines BL0 to BL3 are constructed by mutually connecting terminals D of the nonvolatile variable resistance devices RC17 in the column direction, each of which is connected to a shared electrode serving as the other electrode of the control electrode pair and also as the other electrode of the read electrode pair. According to such a connection configuration, a memory array in the semiconductor apparatus 170 is structured.

In the operation of memory initialization, all the bit lines BL0 to BL3 are connected to ground and a positive pulse is applied to the nonvolatile variable resistance devices RC17 on all the bit lines BL0 to BL3 along the single write-word line WWL0. Herewith, these nonvolatile variable resistance devices RC17 are changed to a high electric resistance state of the same level. By repeating this process to the rest of the write-word lines WWL1 to WWL3, the entire memory array is set to the same, high electric resistance state, and the polarity of the voltage causing the change in electric resistance is also set.

In the normal operation of the memory, while a programming voltage is being applied between a single write-word line (say, WWL(k)) selected from the multiple write-word lines WWL0 to WWL3 and a single bit line (say, BL(l)) selected from the multiple bit lines BL0 to BL3, the remaining write-word lines, read-word lines and bit lines are all set in a floating state so that signals are not transmitted between these word lines and bit lines. Herewith, the electric resistance of a nonvolatile variable resistance device RC17(kl) connected to the selected write-word line WWL(k) and bit line BL(l) is changed.

In the memory array of the semiconductor apparatus 170, data readout is accomplished when a program is executed on the nonvolatile variable resistance devices RC17. While a voltage is being applied across a single read-word line RWL(m) and a single bit line BL(n), the remaining write-word lines, read-word lines and bit lines are all set in a floating state so that signals are not transmitted between the bit line BL(n) and the remaining word lines. By the implementation of such operation, in the memory array of the semiconductor apparatus 170, data is read from a nonvolatile variable resistance device RC17(mn) on which the program has been executed. Subsequently, bit output is read out to bit lines by using a read circuit, which is not shown in the figure.

The semiconductor apparatus 170 of the present embodiment is capable of storing logical values in the variable resistance devices RC17 by corresponding a change in the electric resistance of the variable resistance portion (refer, for example, to Embodiment 3 above), which is located in the variable resistance layer of each nonvolatile variable resistance device RC17, to a logical value. This enables realization of a memory having a simple structure and low power consumption.

[Modification 14]

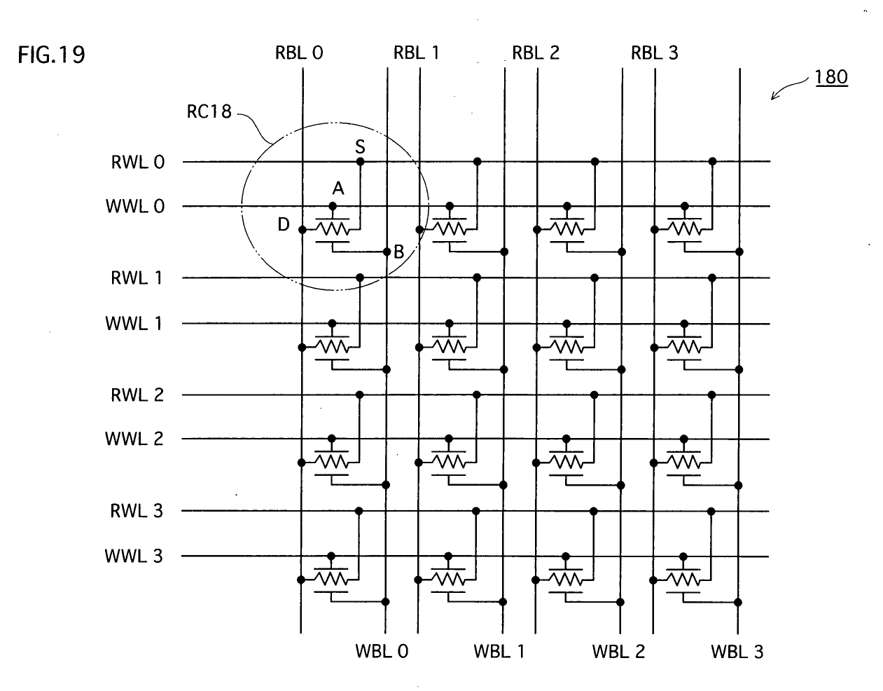

A semiconductor apparatus 180 according to Modification 14 is explained with the aid of FIG. 19. FIG. 19 is a circuit diagram showing part of a memory array in the semiconductor apparatus 180 according to the present modification.

As shown in the figure, the semiconductor apparatus 180 of the present modification differs from the semiconductor apparatus 170 of Embodiment 4 above in using four-terminal nonvolatile variable resistance devices RC18. With the use of these four-terminal devices RC18, the bit lines are divided into write-bit lines WBL0 to WBL3 and read-bit lines RBL0 to RBL3.

In the semiconductor apparatus 180, the four-terminal nonvolatile variable resistance devices RC18 are arranged in a matrix, with each positioned at an intersection of a set of a write-word line and a read-word line WWL0 and RWL0/WWL1 and RWL1/WWL2 and RWL2/WWL3 and RWL3 and a set of a write-bit line and a read-bit line WBL0 and RBL0/WBL1 and RBL1/WBL2 and RBL2/WBL3 and RBL3. FIG. 19 illustrates a 4×4 memory array. Used as the nonvolatile variable resistance devices RC18 are devices having the same structure as any one of the variable resistance devices 10 to 100 according to Embodiments 1 and 2 and Modifications 1 to 8.

The write-word lines WWL0 to WWL3 are respectively constructed by mutually connecting terminals A in the row direction, each of which is connected to one electrode of the control electrode pair of each nonvolatile variable resistance device RC18, while the write-bit lines WBL0 to WBL3 are respectively constructed by mutually connecting terminals B in the column direction, each of which is connected to the other electrode of the control electrode pair. The read-word lines RWL0 to RWL3 are respectively constructed by mutually connecting terminals S in the row direction, each of which is connected to one electrode of the read electrode pair, while the read-bit lines RBL0 to RBL3 are respectively constructed by mutually connecting terminals D in the column direction, each of which is connected to the other electrode of the read electrode pair. According to such a connection configuration, a memory array in the semiconductor apparatus 180 is structured.

In the operation of memory initialization of the semiconductor apparatus 180 having a structure shown in FIG. 19, all the bit lines WBL0 to WBL3 and RBL0 to RBL3 are connected to ground and a positive pulse is applied to the nonvolatile variable resistance devices RC18 on all the bit lines WBL0 to WBL3 and RBL0 to RBL3 along the single write-word line WWL0. Herewith, these nonvolatile variable resistance devices RC18 are changed into a high electric resistance state of the same level. By repeating this process to the rest of the write-word lines WWL1 to WWL3, the entire memory array is set to the same, high electric resistance state, and the polarity of the voltage causing the change in electric resistance is also set.

In the normal operation of the memory, while a programming voltage is being applied between a single write-word line (say, WWL(k)) selected from the multiple write-word lines WWL0 to WWL3 and a single write-bit line (say, WBL(l)) selected from the multiple write-bit lines WBL0 to WBL3, the remaining write-word lines, read-word lines and bit lines are all set in a floating state so that signals are not transmitted between these word lines and bit lines. By executing such a program, the electric resistance of a nonvolatile variable resistance device RC18(kl) connected to the selected write-word line WWL(k) and write-bit line WBL(l) is changed.

Data readout is accomplished when the program is executed on the nonvolatile variable resistance device RC18(kl) as described above. While a voltage is being applied across a single read-word line RWL(k) and a single read-bit line RBL(l) of the nonvolatile variable resistance device RC18(kl), the remaining write-word lines, read-word lines and bit lines are all set in a floating state so that no signals are transmitted between the remaining word lines and the read-bit line RBL(l) of the nonvolatile variable resistance device RC18(kl), on which the program has been executed. By such a process, data is read from the program-executed nonvolatile variable resistance device RC18(kl). Subsequently, bit output is read out to bit lines by using a read circuit, which is not shown in the figure.

The semiconductor apparatus 180 of the present modification is capable of storing logical values in the variable resistance devices RC18 by: (1) applying any type of the variable resistance devices of Embodiments 1 and 2 and Modifications 1 to 8 above for the variable resistance devices RC18; and (2) corresponding a change in the electric resistance of the variable resistance portion, which is located in the variable resistance layer of each nonvolatile variable resistance device RC18, to a logical value. Hereby, the semiconductor apparatus 180 acquires a memory array having a simple structure and low power consumption.

### 5. Embodiment 5

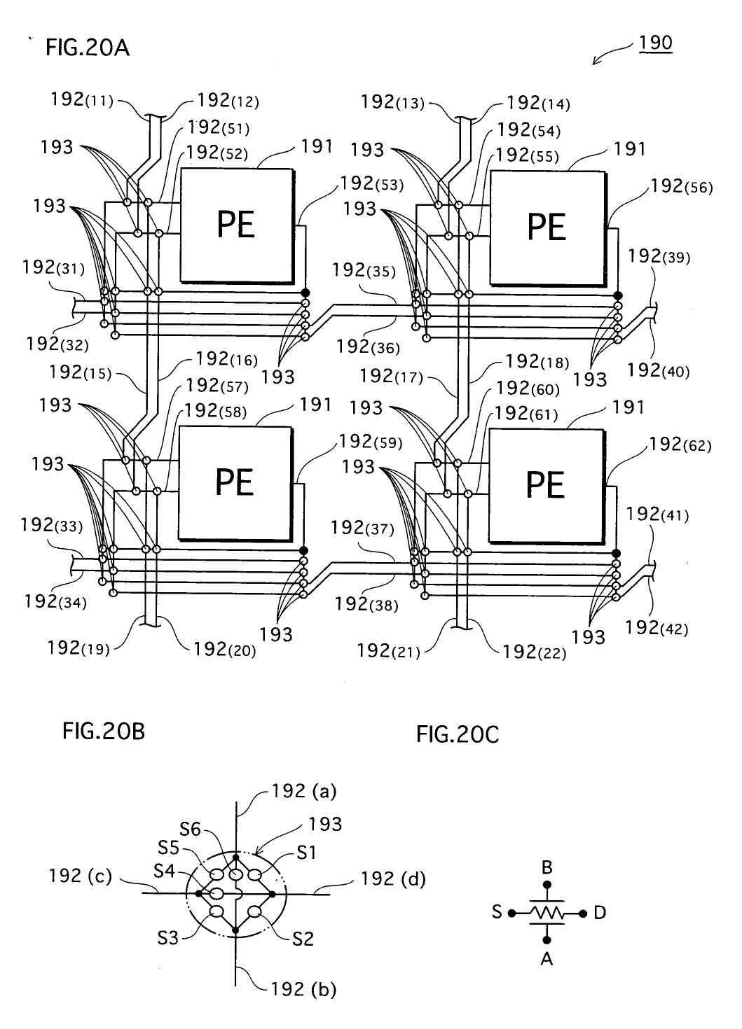

A semiconductor apparatus 190 according to Embodiment 5 is described with the aid of FIGS. 20A to 23.

5.1 Overall Structure of Semiconductor Apparatus 190

FIG. 20A is a block structure diagram of relevant parts showing a programmable logic device of the semiconductor apparatus 190 according to the present embodiment; FIG. 20B is a schematic circuit diagram showing a switch point 193 of the programmable logic device; and FIG. 20C is an equivalent circuit diagram of each nonvolatile variable resistance device used in the switch point 193.

As shown in FIG. 20A, the programmable logic device of the semiconductor apparatus 190 according to the present embodiment comprises: multiple logic circuit cells 191; multiple routing wires 192; and multiple routing switch points 193. Of them, the multiple logic circuit cells 191 are arranged in a matrix, and are connected to each other by routing wires 192₍₁₁₎ to 192₍₂₂₎, routing wires 192₍₃₁₎ to 192₍₄₂₎ and connecting wires 192₍₅₁₎ to 192₍₆₂₎. The switch points 193 are respectively provided at certain cross points of the routing wires 192₍₁₁₎ to 192₍₄₂₎ and connecting wires 192₍₅₁₎ to 192₍₆₂₎.

Each of the switch points 193 is constructed by multiple variable resistance devices, with the same structure as any of the variable resistance devices according to Embodiments 1, 2 and 3 above, functioning as switching elements.

5.2 Structure of Switch Point 193

As shown in FIG. 20B, in each switch point 193 arranged in the semiconductor apparatus 190 of the present embodiment, switches S1 to S6 formed by the variable resistance devices are interposed in routing wires 192₍ₐ₎ to 192_{(d)}. Each of the switches S1 to S6 is formed by a four-terminal nonvolatile variable resistance device which is represented by the equivalent circuit shown in FIG. 20C. That is, any type of the variable resistance devices 10 to 100 according to Embodiments 1 and 2 and Modifications 1 to 8 can be used for the switches S1 to S6. Note that, although write-word lines for applying voltage pulses to the control electrode pairs are respectively connected to the switches S1 to S6, these are not shown in FIGS. 20A and 20B.

5.3 Driving of Semiconductor Apparatus 190

The driving of the semiconductor apparatus 190 is achieved, for example, with the following configuration.

A terminal S of the switch Si (i.e. a terminal connected to one electrode of the read electrode pair of the switch S1) is connected to the routing wire 192₍ₐ₎, and a terminal D of the switch S1 (a terminal connected to the other electrode of the read electrode pair of the switch S1) is connected to the routing wire 192_{(d)}. Then, a voltage pulse is applied between terminals A and B connected to the control electrode pair of the switch S1 once or several times, which causes a change in electric resistance between the terminals S and D. In the case when the electric resistance between the terminals S and D of the switch S1 is shifted to a high electric resistance state, the routing wires 192₍ₐ₎ and 192_{(d)} are disconnected from each other. Contrarily, when the electric resistance between the terminals S and D of the switch S1 is shifted to a low electric resistance state, the routing wires 192₍ₐ₎ and 192_{(d)} are connected to each other. Note that a circuit for applying the voltage pulse to the terminals A and B is not shown in the figure.

5.4 Example of Logic Circuit Cells 191

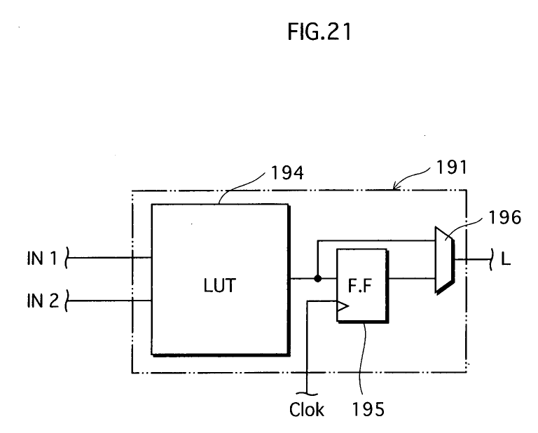

The following gives an example of the logic circuit cells 191 in the semiconductor apparatus 190 with the aid of FIGS. 21 to 23.

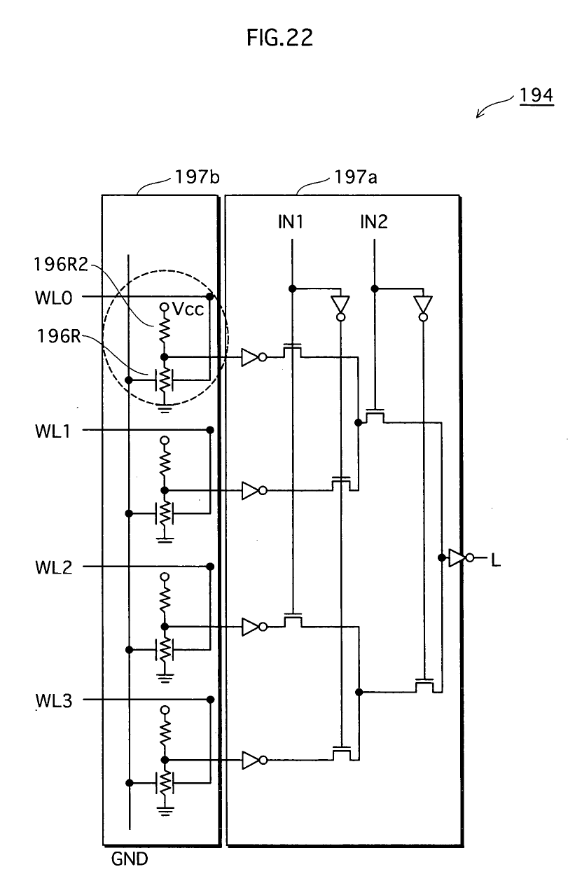

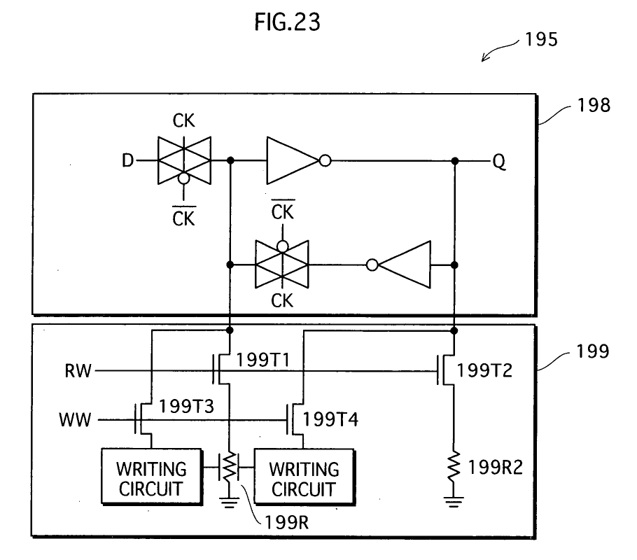

As shown in FIG. 21, each logic circuit cell 191 in the semiconductor apparatus 190 of the present embodiment comprises: a look-up table (LUT) 194; a flip-flop (F.F) 195; and a multiplexer 196. Of them, the look-up table 194 has a structure shown in FIG. 22, while the flip-flop 195 having a structure shown in FIG. 23.

5.4.1 Structure of Look-Up Table 194

As shown in FIG. 22, the look-up table 194 of the logic circuit cell 191 according to the present embodiment has a 2-input 1-output configuration, comprising: a multiplexing unit 197a where input signals IN1 and IN2 are input and an output signal L is output; and a configuration memory unit 197b in which nonvolatile memory cells are arranged in a matrix. In the nonvolatile memory cells of the configuration memory unit 197b, one ends of the control electrodes of four-terminal nonvolatile variable resistance devices 196R are respectively connected to control lines WL0 to WL3, while the other ends are connected to the grounding wire GND.

In addition, one ends of the read electrodes are connected to a power supply Vcc via resistance devices 196R2, while the other ends are connected to ground. Each terminal connecting the four-terminal nonvolatile variable resistance device 196R and the resistance device 196R2 is connected to the multiplexing unit 197a via an inverter. Here, the electric resistance of each resistance device 192R2 functions to set the electric resistance of the corresponding variable resistance device 196R in a high electric resistance state.

The writing operation to the variable resistance devices 196R in the configuration memory unit 197b is executed by applying voltage pulses, for example, between the control lines WL0 to WL3 and the grounding wire GND. In the normal operation, electric potentials of the terminals connecting the variable resistance devices 196R and the resistance devices 196R2 compose configuration data of the look-up table 191.

5.4.2 Structure of Nonvolatile Flip-Flop 195

As shown in FIG. 23, the nonvolatile flip-flop 195 of each logic circuit cell 191 in the semiconductor apparatus 190 according to the present embodiment comprises: a flip-flop circuit unit 198; and a nonvolatile memory unit 199 constructed by using a four-terminal nonvolatile variable resistance device 199R.

Internal nodes of the flip-flop circuit unit 198 are connected to one end of the read electrode of the nonvolatile variable resistance device 199R via a transistor 199T1, while being connected to one end of the control electrode of the nonvolatile variable resistance device 199R via a transistor 199T3 and a writing circuit. The output of the flip-flop circuit unit 198 is connected to one end of a resistance device 199R2 via a transistor 199T2, while being connected to the other end of the control electrode of the nonvolatile variable resistance device 199R via a transistor 199T4 and another wiring circuit. The other end of the read electrode of the nonvolatile variable resistance device 199R and the other end of resistance device 199R2 are respectively connected to ground.

The transistors 199T1 and 199T2 are controlled by a control signal via a read control line RW, while the transistors 199T3 and 199T4 being controlled by a control signal via a write control line WW. The electric resistance of the resistance device 199R2 is set in the range between the electric resistances of the nonvolatile variable resistance device 199R in a high electric resistance state and in a low electric resistance state (desirably, set to a mean value of these electric resistances).

When data is written to the nonvolatile memory unit 199 from the flip-flop circuit unit 198, the transistors 199T1 and 199T2 are off by setting the control signal to the read control line RW to a low state. On the other hand, the transistors 199T3 and 199T4 are on by setting the control signal to the write control line WW to a high state. Herewith, the electric resistance of the nonvolatile variable resistance device 199R in the nonvolatile memory unit 199 is changed, via the writing circuits, according to a value stored in the flip-flop circuit unit 198.

When data is read out to the flip-flop circuit unit 198 from the nonvolatile memory unit 199, the power supply of the flip-flop circuit unit 198 is off in advance. Then, the control signal to the write control line WW is set to a low state while the control signal to the read control line RW being set to a high state, and subsequently, a voltage is applied to the flip-flop circuit unit 198. Herewith, data stored after being allocated with the difference in the electric resistances between the nonvolatile variable resistance device 199R and the resistance device 199R2 is passed along to the flip-flop circuit unit 198. By connecting multiple nonvolatile flip-flops 195 of this kind, a nonvolatile shift register can be composed.

The semiconductor apparatus 190 of the present embodiment achieves realization of a simple structure as well as a reduction in the power consumption by corresponding a change in the electric resistance of each variable resistance portion, which is located in the variable resistance layer of the nonvolatile variable resistance device, to a logical value. In addition, the semiconductor apparatus 190 of the present embodiment is able to achieve a structure having programmable logic devices—such as the nonvolatile flip-flop 195, the nonvolatile look-up table 194 and the nonvolatile register—by applying the nonvolatile variable resistance devices 10 to 100 according to Embodiments 1 and 2 and Modifications 1 to 8 above.

A conventional look-up table having no nonvolatile variable-resistance devices according to Embodiments 1 and 2 above requires constant application of voltage. However, the look-up table 194 of the semiconductor apparatus 190 of the present embodiment is a nonvolatile device since it has the nonvolatile variable resistance devices of, for example, Embodiments 1 and 2 above.

Although the semiconductor apparatus 190 of the present embodiment employs four-terminal nonvolatile variable resistance devices, which are desirable for composing a circuit, three-terminal nonvolatile variable resistance devices according to, for example, Embodiment 3 above can also be used by modifying the circuit structure.

### 6. Embodiment 6

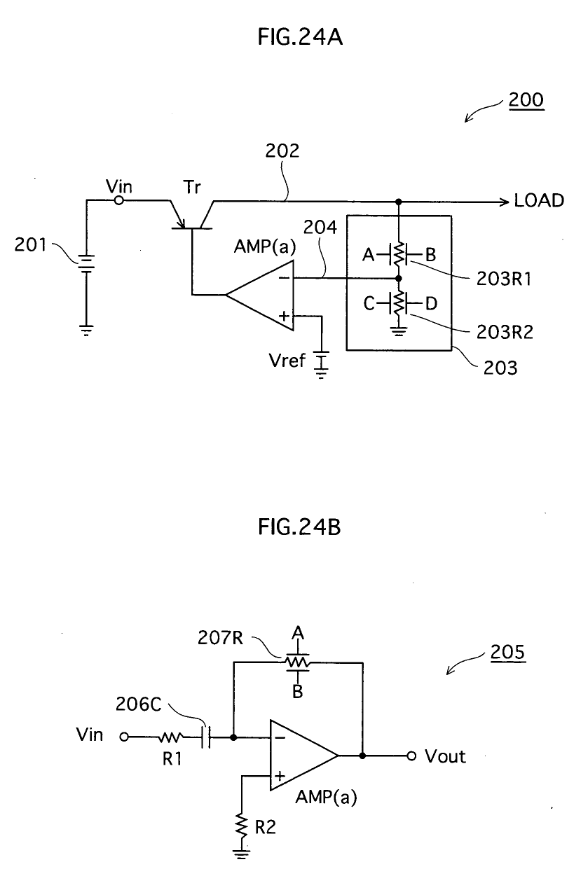

A semiconductor apparatus 200 according to Embodiment 6 is described next with the aid of FIG. 24A. FIG. 24A is a schematic circuit diagram showing a structure of the semiconductor apparatus 200 of Embodiment 6, having an analog power supply circuit formed by using four-terminal nonvolatile variable resistance devices.

As shown in FIG. 24A, in the semiconductor apparatus 200, one end of a battery 201 is connected to ground while the other end is connected to a power supply input terminal Vᵢₙ of the power supply circuit. The power supply input terminal Vᵢₙ is connected to an input (emitter) terminal of a transistor Tr, and an output (collector) terminal of the transistor Tr is connected to a certain load (not shown in the figure) via a power supply line 202. The power supply line 202 is connected to a voltage divider 203, which is connected to an inverting input terminal, “−”, of an operational amplifier AMP₍ₐ₎ via a divided-voltage discharge line 204 for outputting a divided voltage. A non-inverting input terminal, “+”, of the operational amplifier AMP₍ₐ₎ is connected to a reference voltage V_{ref}. The output of the operational amplifier AMP₍ₐ₎ is connected to a control (base) terminal of the transistor Tr.

In the semiconductor apparatus 200, an output voltage from the transistor Tr is devided in the voltage divider 203. The operational amplifier AMP₍ₐ₎ performs feedback control on the divided voltage to be thereby equivalent to a reference voltage of the reference voltage V_{ref}, and outputs the result to the base of the transistor Tr. Thus, the output voltage is controlled to be a predetermined voltage value.

Variations in the electric resistance of a resistance group composing the voltage divider 203 are likely to be brought about during the manufacturing process. Therefore, when tight precision is required for the output voltage, an adjustment is made to the electric resistance so as to tune an electric resistance ratio for the voltage division with a high degree of precision. The voltage divider 203 is composed of four-terminal nonvolatile variable resistance devices 203R1 and 203R2 each having the same structure as, for example, either one of the variable resistance devices 10 and 40 according to Embodiments 1 and 2 above. The electric resistance is adjusted to a desired value by applying voltage pulses between control terminals A and B of the nonvolatile variable resistance device 203R1 as well as between control terminals C and D of the nonvolatile variable resistance device 203R2, with control on the number of the voltage pulses to be applied.

The semiconductor apparatus 200 according to the present embodiment includes the nonvolatile variable resistance devices 203R1 and 203R2 having the same structure as any of the variable resistance devices 10 to 100 above, and changes in the electric resistances of the variable resistance portions (refer to Embodiments 1 and 2 above), which are located in the variable resistance layers of these variable resistance devices 203R1 and 203R2, are modulated. Herewith, an electronic circuit with a simple structure can be realized. Besides, a structure having an analog power supply circuit capable of reducing the power consumption can also be accomplished.

### 7. Embodiment 7

A semiconductor apparatus 205 according to Embodiment 7 is described next with the aid of FIG. 24B. FIG. 24B is a schematic circuit diagram showing a structure of the semiconductor apparatus 205 having an analog differentiation circuit according to the present embodiment.

As shown in FIG. 24B, in the semiconductor apparatus 205, a signal input terminal Vᵢₙ is connected to an inverting input terminal, “−”, of an operational amplifier AMP_{(b)} via a resistance device R1 and a capacitor element 206C. A non-inverting input terminal, “+”, of the operational amplifier AMP_{(b)} is connected to ground via a resistance device R2. In addition, the inverting input terminal, “−”, of the operational amplifier AMP_{(b)} is connected to an output terminal Vₒᵤₜ of the operational amplifier AMP_{(b)} via a four-terminal nonvolatile variable resistance device 207R having the same structure as either one of the variable resistance devices 10 and 40 according to Embodiments 1 and 2 above.

In the semiconductor apparatus 205, the output of a value input to the analog differentiation circuit is determined by values of the capacitor 206C and variable resistance device 207R. Here, the output response is modified by changing the electric resistance of the variable resistance device 207R. The electric resistance is adjusted to a desired value by applying voltage pulses between control terminals A and B of the variable resistance device 207R with control on the number of the voltage pulses to be applied.

The semiconductor apparatus 205 according to the present embodiment includes the nonvolatile variable resistance device 207R having the same structure as any of the variable resistance devices 10 to 100 according to Embodiments 1 and 2 and Modifications 1 to 8 above, and a change in the electric resistance of the variable resistance portion (refer to any of Embodiments 1 and 2 and Modifications 1 to 8 above), which is located in the variable resistance layer of the nonvolatile variable resistance device 207R, is modulated. Herewith, an electronic circuit having a simple structure can be realized. Besides, a structure having an analog differentiation circuit capable of reducing the power consumption can also be accomplished.

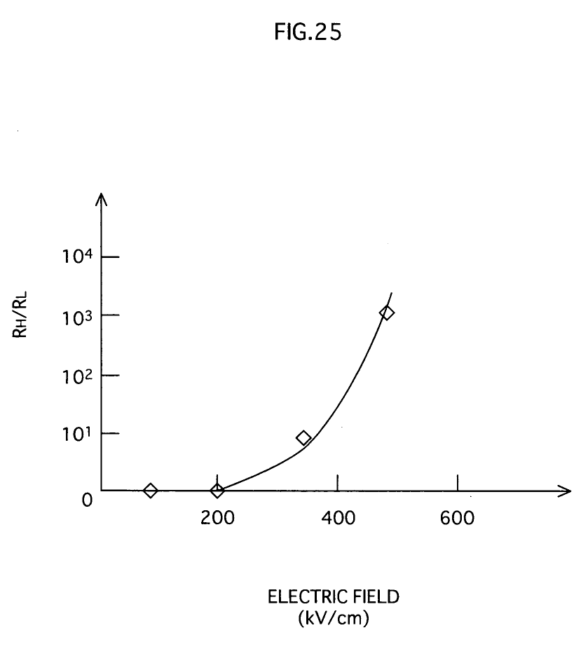

Note that FIG. 25 shows a relationship between the electric field and the rate of electric resistance change of the variable resistance devices 203R1, 203R2 and 207R when nonvolatile variable resistance devices 203R1, 203R2 and 207R are applied to analog circuits as in the case of the semiconductor apparatuses 200 and 205 according to the present embodiment and Embodiment 7 above.

As shown in FIG. 25, regarding the variable resistance devices 203R1, 203R2 and 207R, there is a proportional relationship between the electric field created by the applied voltage pulses and the rate of change in the electric resistance. Thus, when the electric field of the variable resistance portion in the variable resistance layer is changed, the crystal condition of these variable resistance devices has a transition from the metallic phase (a second state exhibiting conducting behavior) to the insulating phase (a first state exhibiting insulating behavior), or to a complex phase in which the metallic and insulating phases coexist (a third state in which the first and second states coexist).

8. Additional Particulars

In Embodiments 1 to 7 and Modifications 1 to 14 above, examples are shown in order to illustrate structural and functional features of the variable resistance devices and semiconductor apparatuses according to the present invention; however, the present invention is not limited to these. For instance, in Embodiments 1 to 3 and Modifications 1 to 13 above, silicon is given as an example of a material for the substrates 11, 21, 31, 41, 51, 61, 71, 81, 91, 101, 111, 121, 131, 141, 151 and 161. However, any appropriate one of LaAlO₃, TiN, and other materials in a monocrystalline, polycrystalline or amorphous state can be used, instead of silicon.

In addition, the following electrodes in Embodiments 1 to 3 and Modifications 1 to 13 above can be formed by conductive oxides or other conductive materials: the 1st electrodes 1A, 2A, 3A, 4A, 5A, 6A, 7A, 8A, 9A, 10A, 11A, 12A, 13A, 14A, 15A and 16A; the 2nd electrodes 1B, 2B, 3B, 4B, 5B, 6B, 7B, 8B, 9B, 10B, 11B, 12B, 13B, 14B, 15B and 16B; the 3rd electrodes 1S, 2S, 3S, 4S, 5S, 6S, 7S, 8S, 9S, 10S, 11S, 12S, 13S, 14S, 15S and 16S; and the 4th electrodes 1D, 2D, 5D, 6D, 9D and 10D. Desirable conductive materials for forming these electrodes are ones allowing materials having a perovskite structure to epitaxially grow on their surface. YBa₂CU₃O₇ (YBCO) and platinum are examples of such.

In Embodiments 1 to 3 and Modifications 1 to 13, Pr_{0.7}Ca_{0.3}MnO₃ (PCMO) is used as an example to form the variable resistance layers 13, 23, 33, 43, 53, 63, 73, 83, 93, 103, 113, 123, 133, 143, 153 and 163. However, materials can be used instead, as long as they (1) have an electric property (i.e. electric resistance) that changes in response to an electric signal, (2) initially have a low electric resistance state, and (3) shift to a high electric resistance state when a voltage pulse is applied once or several times. Specific examples of usable materials are colossal magnetoresistive (CMR) materials and high temperature superconductive (HTSC) materials each having a perovskite structure. Gd_{0.7}Ca_{0.3}BaCo₂O₅₊₅ is an example of high temperature superconductive materials suitable for the use.

In addition, it is desirable that the thickness of the variable resistance layer in the variable resistance devices be in the range of approximately 5 nm to 500 nm.

In the manufacturing process of the variable resistance devices, any appropriate deposition techniques including the following can be used to form the variable resistance layer: pulsed laser deposition; RF sputtering; electron beam evaporation; heat evaporation; metal-organic deposition; sol-gel deposition; and metalorganic chemical vapor deposition.

In Embodiments 2 and 3 and Modifications 3 to 13 above, a material expressed in a chemical composition formula of Ba_{(1-X)}Sr_{X}TiO₃ and having a perovskite structure is given as an example of suitable materials for the high dielectric constant layers 42, 52, 62, 72, 82a, 82b, 92a, 92b, 102a, 102b, 132, 142, 152 and 162. However, the present invention is not limited to this, and high-k materials respectively having a dielectric constant of at least −10% of the dielectric constant of the variable resistance layer in the insulating phase can be employed. One example of such materials is SrTiO₃.

For the formation of the high dielectric constant layers according to Embodiments 2 and 3 and Modifications 3 to 13 above, various deposition techniques can be used including: pulsed laser deposition; RF sputtering; electron beam evaporation; heat evaporation; metal-organic deposition; sol-gel deposition; and metalorganic chemical vapor deposition.

The voltage of a voltage pulse adopted for applying to the variable resistance devices according to Embodiments 1 to 7 and Modifications 1 to 14 above should be in the range capable of changing the electric resistance of the variable resistance portion without impairing the variable resistance layer. Preferably, a voltage pulse achieving an electric field of 350 kV/cm or more is applied, or alternatively a voltage pulse achieving a current density of approximately 1×10⁴ A/cm² is applied. As has been described, the variable resistance devices of the present invention exhibit electric field dependency of the rate of electric resistance change in response to the application of the voltage pulse, as shown in FIG. 25. It can be seen from FIG. 25 that, when the electric field is set to at least 350 kV/cm, the rate of electric resistance change of the variable resistance devices becomes 10 or more, which makes these variable resistance devices be suitable for actual use. In addition, when the variable resistance devices according to the present invention are used as switching elements in an electronic circuit, it is desirable to set the rate of electric resistance change to 100 or more.

In order to change the electric resistance of the variable resistance devices, a method can be adopted in which the number of voltage pulses to be applied is altered while the voltage value and the width of the voltage pulses are maintained at constant. Here, it is desirable that the voltage value and the width of the voltage pulses to be applied to the variable resistance devices be set in the range of 1.2 V to 5 V and in the range of 2 nsec to 3 μsec, respectively. Furthermore, it is advised to set the rise time and fall time of the applied voltage pulses to no more than 10 nsec.

Another method to be adopted for changing the electric resistance of the variable resistance devices is to maintain the voltage value of the voltage pulses at constant while altering the width of the voltage pulses. Here, it is desirable that the voltage value of the voltage pulses to be applied be set in the range of 1.2 V to 5 V, and that the rise time and fall time of the voltage pulses be no more than 10 nsec.

Still further alternatively, in order to change the electric resistance of the variable resistance devices, a method can be adopted in which the width of the voltage pulses is maintained at constant while the voltage value of the voltage pulses to be applied is altered. Here, it is desirable that the width of the voltage pulses to be applied be set in the range of 2 nsec to 3 μsec, and that the rise time and fall time of the voltage pulses be no more than 10 nsec.

Although the present invention has been fully described by way of examples with reference to the accompanying drawings, it is to be noted that various changes and modifications will be apparent to those skilled in the art. Therefore, unless such changes and modifications depart from the scope of the present invention, they should be constructed as being included therein.

What is claimed is:

1. A variable resistance device comprising:
a variable resistance layer made of a material which has an electric resistance changing in accordance with an applied electric field and maintains the electric resistance after being changed in a nonvolatile manner;
a control electrode pair, which consists of a 1st and a 2nd electrode respectively connected to the variable resistance layer so as to be independent of each other, being used for applying voltage to the variable resistance layer; and
a read electrode, which is a 3rd electrode connected to the variable resistance layer so as to be independent of the 1st and the 2nd electrodes, being used for detecting the electric resistance.

2. The variable resistance device of claim 1, wherein
the 3rd electrode and one of the 1st and the 2nd electrodes constituting the control electrode pair constitute a read electrode pair.

3. The variable resistance device of claim 2, wherein
the electrodes constituting the control electrode pair are arranged to sandwich an entire or part of the variable resistance layer therebetween in a thickness direction of the variable resistance layer, and
the electrodes constituting the read electrode pair are positioned so that at least part of a section, within the variable resistance layer, sandwiched between the control electrode pair is included in a target path for detecting the electric resistance.

4. The variable resistance device of claim 3, wherein
within the variable resistance layer, a straight line drawn between the electrodes constituting the control electrode pair and a straight line drawn between the electrodes constituting the read electrode pair differ from each other, forming an angle therebetween.

5. The variable resistance device of claim 1, wherein
a 4th electrode is connected to the variable resistance layer so as to be independent of the respective 1st, 2nd and 3rd electrodes, and
the 3rd and the 4th electrodes constitute a read electrode pair.

6. The variable resistance device of claim 1, wherein
a high dielectric constant layer, having a dielectric constant of at least 90% of a dielectric constant of the variable resistance layer in an insulating phase, is interposed between the variable resistance layer and at least one of the electrodes constituting the control electrode pair.

7. The variable resistance device of claim 6, wherein
the high dielectric constant layer has an electric resistivity equivalent to or greater than an electric resistivity of the variable resistance layer in the insulating phase.

8. The variable resistance device of claim 6, wherein
the high dielectric constant layer includes a material expressed in a chemical composition formula of A_{X}B_{Y}, where
A is at least one element selected from the group consisting of Al, Hf, Zr, Ti, Ba, Sr, Ta, La, Si, and Y, and B is at least one element selected from the group consisting of O, N, and F.

9. The variable resistance device of claim 1, wherein
when a voltage pulse is applied to the control electrode pair once or a plurality of times, crystal condition of a portion, within the variable resistance layer, affected by the voltage pulse turns into one of a metallic phase and an insulating phase depending on a polarity of the voltage pulse.

10. The variable resistance device of claim 9, wherein
each phase state of the metallic and the insulating phases is defined by at least one of the group consisting of a number of times, a pulse width, and a voltage of the applied voltage pulse.

11. The variable resistance device of claim 1, wherein
the variable resistance layer includes a colossal magnetoresistive material having a perovskite structure.

12. The variable resistance device of claim 1, wherein
the variable resistance layer includes a material expressed in a chemical composition formula of A_{X}A′_{(1-X)}B_{Y}O_{Z}, where
A is at least one element selected from the group consisting of La, Ce, Bi, Pr, Nd, Pm, Sm, Y, Sc, Yb, Lu, and Gd,
A′ is at least one element selected from the group consisting of Mg, Ca, Sr, Ba, Pb, Zn, and Cd,
B is at least one element selected from the group consisting of Mn, Ce, V, Fe, Co, Nb, Ta, Cr, Mo, W, Zr, Hf, and Ni,
0≦X≦1,
0≦Y≦2, and
1≦Z≦7.

13. The variable resistance device of claim 1, wherein
the variable resistance layer includes a material expressed in a chemical composition formula of Pr_{0.7}Ca_{0.3}MnO₃.

14. A semiconductor apparatus comprising:
at least one variable resistance device including:
a variable resistance layer made of a material which has an electric resistance changing in accordance with an applied electric field and maintains the electric resistance after being changed in a nonvolatile manner;
a control electrode pair, which consists of a 1st and a 2nd electrode respectively connected to the variable resistance layer so as to be independent of each other, being used for applying voltage to the variable resistance layer; and
a read electrode, which is a 3rd electrode connected to the variable resistance layer so as to be independent of the 1st and the 2nd electrodes, being used for detecting the electric resistance.

15. The semiconductor apparatus of claim 14, wherein
a plurality of variable resistance devices, each the same as the variable resistance device, are provided and arranged in a matrix, constituting a nonvolatile memory.

16. The semiconductor apparatus of claim 14, wherein
the variable resistance device is connected to a flip-flop, which thereby constitutes a nonvolatile flip-flop, and
in the nonvolatile flip-flop, the variable resistance device carries out a data backup function during when power supply to the flip-flop is off.

17. The semiconductor apparatus of claim 16, wherein
a plurality of nonvolatile flip-flops, each the same as the nonvolatile flip-flop, are provided and connected to each other, which thereby constitutes a nonvolatile shift register.

18. The semiconductor apparatus of claim 14, wherein
the variable resistance device constitutes a configuration memory, and
the configuration memory together with a multiplexer constitutes a nonvolatile look-up table.

19. The semiconductor apparatus of claim 14, wherein
the variable resistance device functions as a switching element.

20. The semiconductor apparatus of claim 14, further comprising:
a plurality of logic device cells, wherein
the variable resistance device is inserted into connection paths, and
the connection paths are arranged between each of the plurality of logic device cells, which thereby constitutes a programmable logic circuit.
